(19) United States
(12) Patent Application Publication
(10) Pub. No.: US 2023/0240089 A1
(43) Pub. Date: Jul. 27, 2023

(54) QUANTUM DOT ENSEMBLE AND MANUFACTURING METHOD THEREOF, QUANTUM DOT ENSEMBLE LAYER, AND IMAGING DEVICE

(71) Applicant: Sony Group Corporation, Tokyo (JP)

(72) Inventors: Shunsuke YAMASHITA, Tokyo (JP); Mamoru TANABE, Tokyo (JP); Syuuiti TAKIZAWA, Tokyo (JP); Michinori SHIOMI, Tokyo (JP)

(21) Appl. No.: 17/928,774

(22) PCT Filed: May 18, 2021
(86) PCT No.: PCT/JP2021/018737

§ 371 Date: Nov. 30, 2022

(30) Foreign Application Priority Data
Jun. 3, 2020 (JP) 2020-096604

(51) Int. Cl. H10K 50/115; B82Y 30/00; B82Y 40/00; H10K 71/40

(52) U.S. Cl. CPC H10K 50/115; B82Y 30/00; B82Y 40/00; H10K 71/40

(57) ABSTRACT

A manufacturing method of a quantum dot ensemble of the present disclosure is a manufacturing method of a quantum dot ensemble including a plurality of core-shell quantum dots 10A that each includes a core 10B including a compound semiconductor, and a shell 10C including a compound semiconductor and covering the core, and a ligand 10D coordinated to the shell, and the manufacturing method includes mixing a core material, a shell material, and the ligand in a solvent and thereafter performing heating to thereby form the core-shell quantum dots, coordinate the ligand to the shell, and cleave the ligand.

### TECHNICAL FIELD

The present disclosure relates to a quantum dot ensemble and a manufacturing method thereof, a quantum dot ensemble layer, and an imaging device.

### BACKGROUND ART

In a case where a quantum dot (semiconductor nanoparticle) ensemble is applied to a sensor, an imaging element, a light-receiving element, and the like, in order to obtain a quantum dot ensemble having superior characteristics, it is preferable to form a high-density quantum dot ensemble. As a method of forming a high-density quantum dot ensemble, for example, PTL 1 discloses the following method. That is, PTL 1 discloses a manufacturing method of a semiconductor film including a semiconductor quantum dot ensemble formation process of applying, onto a substrate, a semiconductor quantum dot dispersion liquid that includes an ensemble of semiconductor quantum dots each having a metal atom, first ligands coordinated to respective semiconductor quantum dots, and a first solvent to form an ensemble of semiconductor quantum dots, and a ligand exchange process of applying, to the ensemble of semiconductor quantum dots, a solution that includes second ligands having a molecular chain length shorter than that of the first ligands and a second solvent to replace the first ligands coordinated to the semiconductor quantum dots by the second ligands, thereby obtaining a semiconductor film in which the semiconductor quantum dots have an average shortest inter-dot distance of greater than 0.0 nm and less than 0.45 nm.

### CITATION LIST

### Patent Literature

PTL 1: Japanese Patent No. 5964744

### SUMMARY OF THE INVENTION

In the technology disclosed in PTL 1, replacing first ligands by second ligands makes it possible to obtain a semiconductor film in which semiconductor quantum dots have a average shortest inter-dot distance of greater than 0.0 nm and less than 0.45 nm, thereby making it possible to obtain a high-density semiconductor film. However, after an ensemble of semiconductor quantum dots is formed, the first ligands are replaced by the second ligands, which causes an issue that contamination by an impurity easily occurs at this time.

It is therefore desirable to provide a manufacturing method of a high-density quantum dot ensemble resistant to contamination by an impurity during manufacturing, a high-density quantum dot ensemble and a high-density quantum dot ensemble layer that are obtained by the manufacturing method, and an imaging device including an imaging element that includes the quantum dot ensemble layer.

A manufacturing method of a quantum dot ensemble according to a first aspect of the present disclosure is a manufacturing method of a quantum dot ensemble including a plurality of core-shell quantum dots that each includes a core including a compound semiconductor, and a shell including a compound semiconductor and covering the core, and a ligand coordinated to the shell, the manufacturing method including mixing a core material, a shell material, and the ligand in a solvent and thereafter performing heating to thereby form the core-shell quantum dots, coordinate the ligand to the shell, and cleave the ligand.

A manufacturing method of a quantum dot ensemble according to a second aspect of the present disclosure is a manufacturing method of a quantum dot ensemble including a plurality of core-shell quantum dots that each includes a core including a compound semiconductor, and a shell including a compound semiconductor and covering the core, and a ligand coordinated to the shell, the manufacturing method including preparing the core-shell quantum dots and mixing the quantum dots and the ligand in a solvent and thereafter performing heating to thereby coordinate the ligand to the shell and cleave the ligand.

A quantum dot ensemble of the present disclosure includes a plurality of core-shell quantum dots that each includes a core including a compound semiconductor, and a shell including a compound semiconductor and covering the core; and a ligand coordinated to the shell, the ligand including an alkane that has an average carbon number of 1 or more and 3 or less and includes a chalcogen atom at one end.

A quantum dot ensemble layer of the present disclosure includes a quantum dot ensemble shaped into a layer, the quantum dot ensemble including a plurality of core-shell quantum dots that each includes a core including a compound semiconductor, and a shell including a compound semiconductor and covering the core, and a ligand coordinated to the shell, and the ligand including an alkane that has an average carbon number of 1 or more and 3 or less and includes a chalcogen atom at one end.

An imaging device of the present disclosure includes a plurality of imaging elements arranged, the imaging elements each having a stacked structure in which a first electrode, a photoelectric conversion layer including a quantum dot ensemble layer, and a second electrode are stacked, the quantum dot ensemble layer including a quantum dot ensemble shaped in a layer, the quantum dot ensemble including a plurality of core-shell quantum dots that each includes a core including a compound semiconductor, and a shell including a compound semiconductor and covering the core, and a ligand coordinated to the shell, and the ligand including an alkane that has an average carbon number of 1 or more and 3 or less and includes a chalcogen atom at one end.

### BRIEF DESCRIPTION OF DRAWINGS

FIGS. 1A and 1B are schematic partial cross-sectional views of a quantum dot ensemble layer, a base, and a functional layer in Example 1, and FIG. 1C is a conceptual diagram of a quantum dot ensemble of Example 1.

FIGS. 2A and 2B are respectively a chart illustrating 1H-NMR measurement results in Example 1 and a graph illustrating a relationship of a heating temperature, quantum dot coverage, and an average distance (inter-quantum dot average distance).

FIG. 3 is a schematic partial cross-sectional view of an imaging element of Example 3.

FIG. 4 is a schematic partial cross-sectional view of Modification Example-1 of the imaging element of Example 3.

FIG. 5 is a schematic partial cross-sectional view of Modification Example-2 of the imaging element of Example 3.

FIGS. 6A and 6B each are an equivalent circuit diagram of the imaging element of Example 3.

FIG. 7 is an equivalent circuit diagram of Modification Example-2 of the imaging element of Example 3.

FIG. 8 is a schematic layout diagram of a first electrode and a charge accumulation electrode, and transistors included in a controller that are included in the imaging element of Example 3.

FIG. 9 is a diagram schematically illustrating a state of a potential in each part during an operation of the imaging element of Example 3.

FIG. 10 is a conceptual diagram of an imaging device of Example 3.

FIG. 11 is a block diagram illustrating a configuration example of an imaging device in a case where the imaging device of Example 3 is applied to an electronic apparatus.

FIG. 12 is a conceptual diagram of an example of using an imaging device including an imaging element of the present disclosure in an electronic apparatus (camera).

FIG. 13 is a schematic partial cross-sectional view of an imaging element including a transfer control electrode (charge transfer electrode) of Example 4.

FIGS. 14A and 14B each are an equivalent circuit diagram of the imaging element of Example 4.

FIG. 15 is a schematic layout diagram of a first electrode, the transfer control electrode, and a charge accumulation electrode, and transistors included in a controller that are included in the imaging element of Example 4.

FIG. 16 is a diagram schematically illustrating a state of a potential in each part during an operation of the imaging element of Example 4.

FIG. 17 is a diagram schematically illustrating the state of the potential in each part during the operation of the imaging element of Example 4.

FIG. 18 is a schematic partial cross-sectional view of a light-emitting element (specifically, a VCSEL) that is an example to which a quantum dot ensemble layer of Example 5 is applied.

FIG. 19 is a block diagram depicting an example of schematic configuration of a vehicle control system.

FIG. 20 is a diagram of assistance in explaining an example of installation positions of an outside-vehicle information detecting section and an imaging section.

FIG. 21 is a view depicting an example of a schematic configuration of an endoscopic surgery system.

FIG. 22 is a block diagram depicting an example of a functional configuration of a camera head and a camera control unit (CCU).

### MODES FOR CARRYING OUT THE INVENTION

In the following, description is given of the present disclosure on the basis of Examples with reference to the drawings. However, the present disclosure is not limited to Examples, and various numerical values and materials in Examples are illustrative. It is to be noted that the description is given in the following order.

### 1. General Description of Manufacturing Methods of Quantum Dot Ensemble According to First and Second Aspects of Present Disclosure, and Quantum Dot Ensemble and Quantum Dot Ensemble Layer of Present Disclosure

### 2. Example 1 (Manufacturing Method of Quantum Dot Ensemble According to First Aspect of Present Disclosure, and Quantum Dot Ensemble and Quantum Dot Ensemble Layer of Present Disclosure)

### 3. Example 2 (Manufacturing Method of Quantum Dot Ensemble According to Second Aspect of Present Disclosure)

### 4. Example 3 (Application Example of Quantum Dot Ensemble Layer Described in Examples 1 and 2, Imaging Element, and Imaging Device)

### 5. Example 4 (Modification of Example 3)

### 6. Example 5 (Application Example of Quantum Dot Ensemble Layer Described in Examples 1 and 2, and Light-emitting Element)

### 7. Others

### <General Description of Manufacturing Methods of Quantum Dot Ensemble According to First and Second Aspects of Present Disclosure, and Quantum Dot Ensemble and Quantum Dot Ensemble Layer of Present Disclosure>

In manufacturing methods of a quantum dot ensemble according to first and second aspects of the present disclosure, a mode may be adopted in which heating conditions include 230° C. or higher for 0.5 hours or more.

In the manufacturing methods of the quantum dot ensemble according to the first and second aspects of the present disclosure including the preferred mode described above, a mode may be adopted in which an alkane includes a chalcogen atom (Group 16 element) at one end, and the chalcogen atom is a part of chalcogen atoms included in a front surface of a shell. In addition, a ligand before being cleaved preferably includes an alkane having a carbon number of 6 or more and including a chalcogen atom (specifically, a sulfur atom, a selenium atom, or a tellurium atom, and the same applies hereinafter) at one end. In general, a chain hydrocarbon having only carbon-carbon single bonds is referred to as an “alkane”; however, in the present specification, the “alkane” includes a chain hydrocarbon in which some of carbon-carbon single bonds are double-bonded or triple bonded. The same applies hereinafter. In addition, in this case, a cleaved ligand preferably includes an alkane including a chalcogen atom (Group 16 element) at one end and having an average carbon number of 1 or more and 3 or less. It is to be noted that an alkane included in the cleaved ligand is a chain hydrocarbon having only a carbon-carbon single bond. The same applies hereinafter. Furthermore, in these cases, the ligand before being cleaved includes alkanethiol, alkaneselenol, or alkanetellurol, and specific examples thereof may include dodecanethiol <CH3(CH2)11SH> or dodecaneselenol <CH3(CH2)11SeH>.

Furthermore, in the manufacturing methods of the quantum dot ensemble according to the first and second aspects of the present disclosure including the preferred modes described above, or in a quantum dot ensemble of the present disclosure or a quantum dot ensemble layer of the present disclosure, a mode may be adopted in which the shell includes a sulfide, a selenide, or a telluride. Specifically, a mode may be adopted in which the shell includes at least one kind of material selected from a group including ZnS, ZnSe, ZnTe, CdS, and CdSe. The chalcogen atom is a part of chalcogen atoms included in the front surface of the shell, that is, the chalcogen atom at the one end of the ligand and the chalcogen atom included in the shell are preferably the same atoms. More specifically, in a case where the shell includes a sulfide, the chalcogen atom at the one end of the ligand preferably includes a sulfur (S) atom. That is, for example, the one end of the ligand preferably includes thiol. In addition, in a case where the shell includes a selenide, the chalcogen atom at the one end of the ligand preferably includes a selenium (Se) atom. That is, for example, the one end of the ligand preferably includes selenol. Furthermore, in a case where the shell includes a telluride, the chalcogen atom at the one end of the ligand preferably includes a tellurium (Te) atom. That is, for example, the one end of the ligand preferably includes tellurol.

Furthermore, in the manufacturing methods of the quantum dot ensemble according to the first and second aspects of the present disclosure including the preferred modes described above, or in the quantum dot ensemble of the present disclosure or the quantum dot ensemble layer of the present disclosure including the preferred modes described above, a mode my be adopted in which a core includes a compound semiconductor of Group 4 to Group 6, a compound semiconductor of Group 3 to Group 5, a compound semiconductor of Group 2 to Group 6, or a compound semiconductor including a combination of three or more elements of Group 2, Group 3, Group 4, Group 5, and Group 6. Specific examples of a material included in the core may include, but are not limited to: Si; Ge; chalcopyrite-based compounds including CIGS (CuInGaSe), CIS (CuInSe2), CuInS2, CuAlS2, CuAlSe2, CuGaS2, CuGaSe2, AgAlS2, AgAlSe2, AgInS2, AgInSe2, perovskite-based materials; Group III-V compounds including GaAs, GaP, InP, InN, InAs, InSb, InGaAs, AlGaAs, InGaP, AlGaInP, InGaAsP, and GaN; CdSe, CdSeS, CdS, CdTe, In2Se3, In2S3, Bi2Se3, Bi2S3, ZnSe, ZnTe, ZnS, HgTe, HgS, PbSe, PbS, TiO2, AgS, AgSe, AgTe, and the like. It is sufficient if the quantum dot ensemble layer of the present disclosure includes at least one kind of quantum dot. The quantum dot ensemble layer of the present disclosure may include a plurality of kinds of quantum dots. In addition, a material included in the core and a material included in the shell may form a solid solution.

Alternatively, a mode may be adopted in which the core includes a semiconductor material having a relatively narrow band gap. As the size (diameter) of the quantum dot becomes smaller, the band gap energy becomes higher, and the wavelength of light emitted from the quantum dot or light absorbed by the quantum dot becomes shorter. That is, as the size of the quantum dot is smaller, light having a shorter wavelength (light on blue light side) is emitted or absorbed, and as the size of the quantum dot is larger, light having a longer wavelength (light on red light side) is emitted or absorbed. Therefore, fixing the material of a quantum dot and adjusting the size of the quantum dot makes it possible to obtain a quantum dot that emits or absorbs light having a desired wavelength (performing color conversion into a desired color).

Furthermore, in the manufacturing methods of the quantum dot ensemble according to the first and second aspects of the present disclosure including the preferred modes described above, or in the quantum dot ensemble of the present disclosure or the quantum dot ensemble layer of the present disclosure including the preferred modes described above, it is desirable that an average distance (hereinafter referred to as an “inter-quantum dot average distance”) between a quantum dot and a quantum dot be greater than 0 nm and 1 nm or less, preferably 0.1 nm or greater and 1.0 nm or less.

Here, it is possible to calculate the inter-quantum dot average distance with use of a Fourier transform pattern of a scanning transmission electron microscope image (STEM image). That is, it is possible to determine, from the Fourier transform pattern of the STEM image, an interval in an in-plane direction between quantum dots, in other words, a distance between the centers of a quantum dot and a quantum dot. This value is an average value of the distances between the centers of adjacent quantum dots in all quantum dots included in the STEM image; therefore, it is possible to calculate an average value of the inter-quantum dot average distances by subtracting, from this value, an average particle diameter of quantum dots to be described later. It is possible to measure an inter-quantum dot average distance when a quantum dot ensemble layer is formed on a base or a functional layer to be described later on the basis of a grazing incidence small angle X-ray scattering method (GISAXS method). It is possible to determine the interval in the in-plane direction between quantum dots, that is, the distance between the centers of a quantum dot and a quantum dot, from an X-ray scattering pattern that is able to be obtained by the GISAXS method. This value is an average value of the distances between the centers of adjacent quantum dots in all quantum dots existing in an X-ray irradiated region; therefore, it is possible to calculate the average value of the inter-quantum dot average distances by subtracting, from this value, the average particle diameter of the quantum dots to be described later.

Furthermore, in the quantum dot ensemble of the present disclosure including the preferred modes described above, a mode may be adopted in which a dispersion medium is further included, and the quantum dot ensemble (corresponding to a dispersoid or a disperse phase) is disposed in the dispersion medium, that is, a mode may be adopted in which a disperse system is configured. Such a mode is referred to as a “quantum dot dispersion liquid” for the sake of convenience. Here, the “dispersion medium” indicates a homogeneous substance that forms a medium of a disperse system, specifically, an organic solvent or a solution. More specifically, it is sufficient if the dispersion medium uses a solvent used in manufacturing of the quantum dot ensemble as it is. Alternatively, a solvent different from the solvent used in manufacturing of the quantum dot ensemble may be used.

It is desirable that a constituent material of the quantum dots have a band gap of 2.5 eV or less as a bulk.

It is possible to evaluate the structure of the quantum dot on the basis of a transmission electron microscope image, a scanning transmission electron microscope image, and an energy dispersive X-ray spectroscopy method (EDX method). It is possible to prepare a sample to be used for evaluation by dropping the quantum dot dispersion liquid onto a TEM grid and drying the quantum dot dispersion liquid. It is possible to determine the particle diameter of the quantum dot from an TEM image photographed with use of a TEM. Specifically, among line segments connecting any two points on an outer periphery of the quantum dot, the longest line segment is the particle diameter. The average particle diameter is determined as follows. After an image (with a photographing magnification of 50000 times to 1000000 times) including 100 or more quantum dots is photographed, the particle diameters of all the quantum dots are measured, and the average particle diameter is determined by an arithmetic mean of these particle diameters. In a case where the number of quantum dots included in one TEM image is less than 100, the average particle diameter may be calculated with use of a plurality of TEM images. It is possible to confirm formation of a core-shell structure by measuring a distribution of each element included in the quantum dot by STEM-EDX and confirming that many elements included in the shell are distributed on front surface side of the quantum dot. It is desirable that the average particle diameter of the quantum dots be 2 nm to 15 nm.

It is possible to calculate quantum dot coverage (covering density of ligands, that is, how many ligands are bonded per unit area of the front surface of the shell included in the quantum dot) by NMR measurement. Specifically, it is possible to calculate the quantum dot coverage by dividing the total number of absorbed ligands included in the quantum dot dispersion liquid used for NMR measurement by the total of surface areas of quantum dots included in the quantum dot dispersion liquid. It is possible to estimate the total number of absorbed ligands by comparing a peak area of ligands (may be referred to as “absorbent ligands”) absorbed to the shells in a 1H-NMR spectrum with a peak area of a reference sample whose concentration is known. It is possible to estimate the total of surface areas of the quantum dots by the number of quantum dots included in a solution and the average particle diameter of the quantum dots.

It is possible to evaluate the cleavage degree of the ligand by shifting of the peak position of the absorbent ligand in a 1H-NMR spectrum. For example, in a case where the ligand is dodecanethiol, the peak of hydrogen bonded to carbon adjacent to thiol in the absorbent ligand appears around 2.7 ppm, and peak intensity around 2.7 ppm is attenuated with an increase in heating temperature, and the peak position is shifted to low magnetic field side. This corresponds to progress of C—S bond cleavage in dodecanethiol progressing around a heating temperature of 230° C., and it is possible to evaluate cleavage of the ligand by shifting of the peak position. The cleaved ligand is pyrolyzed at 400° C. to 600° C. with use of a pyrolyzer, and GCMS (Gas Chromatography Mass spectrometry) measurement of a decomposed substance is performed, which makes it possible to specify the cleavage degree.

In a case where the inter-quantum dot average distance is long, electrical conductivity decreases to cause the quantum dot ensemble layer to become an insulator. Shortening the inter-quantum dot average distance makes it possible to improve electrical conductivity and obtain, for example, a quantum dot ensemble layer having a high photocurrent value. The thickness of the quantum dot ensemble layer is not specifically limited, but is preferably 10 nm or more, and more preferably 50 nm or more in terms of obtaining high electrical conductivity. The thickness of the quantum dot ensemble layer is preferably 0.3 μm or less in terms of a possibility that carrier concentration becomes excessive, and ease of manufacturing.

In the manufacturing method of the quantum dot ensemble according to the first aspect of the present disclosure and the manufacturing method of the quantum dot ensemble according to the second aspect of the present disclosure are described in detail later. It is to be noted that in a case where a core material, a shell material, and a ligand are mixed in a solvent, or when quantum dots and the ligand are mixed in a solvent, a dispersant (e.g., oleic acid or oleylamine) may be added to prevent aggregation of the core material.

The quantum dot ensemble layer is shaped into a layer on the base, or is shaped into a layer on the functional layer provided on the base. For formation of the quantum dot ensemble layer, it is sufficient if the quantum dot dispersion liquid is formed on the base or is formed on the functional layer provided on the base. Examples of the functional layer may include an adhesion improvement layer for improving adhesion between the base and the quantum dot ensemble, a transparent electrically-conductive layer, various insulating layers, a layer in which various circuits are formed, and a layer in which various constituent elements included in a sensor or the like to be described later are formed. The base includes a base in which various circuits are formed, or a base in which various constituent elements included in a sensor or the like to be described later are formed.

The content of the quantum dots in 1 milliliter of the quantum dot dispersion liquid is preferably 1 milligram to 100 milligrams, and more preferably 5 milligrams to 40 milligrams. It is sufficient if the dispersion medium uses a solvent used in manufacturing of the quantum dot ensemble as it is, and the solvent may be further added to optimize viscosity of the quantum dot dispersion liquid. Alternatively, a solvent different from the solvent used in manufacturing of the quantum dot ensemble may be used.

Examples of a method of applying a liquid material as a method of forming a quantum dot dispersion liquid on the base or the functional layer may include various coating methods, specifically, a screen printing method; a spin coating method; a dipping method; a casting method; various printing methods including an ink jet printing method, an offset printing method, a reverse offset printing method, a gravure printing method, and a micro contact method; a stamping method; a spray method; a nanoimprinting method; various coating methods including an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, a calendar coater method, and a capillary coater method; a method using a dispenser; a casting method; and a stamping method.

The shape, structure, size, and the like of the base are not specifically limited, and may be selected as appropriate depending on a purpose. The structure of the base may be a single-layer structure or a multilayer structure. Examples of the base may include a glass plate, an inorganic material plate such as yttrium-stabilized zirconium, a plastic film, a plastic sheet, a composite material plate, a composite material sheet, and a composite material film. Among them, the plastic film, the plastic sheet, the composite material plate, the composite material sheet, and the composite material film are preferably used because of a light weight and flexibility. The plastic film and the plastic sheet are collectively referred to as a “plastic film and the like”, and the composite material plate, the composite material sheet, and the composite material film are collectively referred to as a “composite material sheet and the like”.

Examples of a resin included in the plastic film and the like may include resins such as polybutylene terephthalate, polyethylene terephthalate, polyethylene naphthalate, polybutylene naphthalate, polystyrene, polycarbonate, polysulfone, polyethersulfone, polyarylate, allyl diglycol carbonate, polyamide, polyimide, polyamide imide, polyetherimide, polybenzoxazole, polyphenylene sulfide, polycycloolefin, a norbornene resin, a vinyl chloride resin, a fluorine resin such as polychlorotrifluoroethylene, a liquid crystal polymer, an acrylic resin, an epoxy resin, a silicone resin, an ionomer resin, a cyanate resin, crosslinked fumaric acid diester, cyclic polyolefin, aromatic ether, maleimide olefin, cellulose, and an episulfide compound.

Examples of the composite material sheet and the like including a composite material of an inorganic material and a resin may include a composite material of the resin and any of the following inorganic materials. That is, specific examples thereof may include a composite material of the resin and silicon oxide particles, a composite material of the resin and metal nanoparticles, a composite material of the resin and inorganic oxide nanoparticles, a composite material of the resin and inorganic nitride nanoparticles, a composite material of the resin and carbon fibers, a composite material of the resin and carbon nanotubes, a composite material of the resin and glass flakes, a composite material of the resin and glass fibers, a composite material of the resin and glass beads, a composite material of the resin and a clay mineral, a composite material of the resin and mica, a composite material (stacked structure) of the resin and glass, a composite material (stacked structure) of an inorganic layer and an organic layer. Examples of the resin may include a resin included in the plastic film and the like described above.

Alternatively, as the base, it is possible to use a stainless steel substrate, a metal substrate in which stainless steel and a different metal are stacked, an aluminum substrate, or an aluminum substrate with an oxidation film in which insulation of a front surface is improved by performing an oxidation process (e.g., an anode oxidation process) on the front surface.

The base including the plastic film or the like or the composite material sheet or the like is preferably superior in heat resistance, dimension stability, solvent resistance, electrical insulation, workability, low air permeability, low hygroscopicity, and the like. These bases may include a gas barrier layer for preventing transmission of water, oxygen, and the like, an undercoat layer for improving flatness of a resin substrate, for example, adhesion to a lower electrode, or the like.

The thickness of the base is not specifically limited, but is preferably 5×10⁻⁵ m to 1×10⁻³ m, and more preferably 5×10⁻⁵ m to 5×10⁻⁴ m in consideration of flatness and flexibility of the base.

The quantum dot ensemble or the quantum dot ensemble layer of the present disclosure may be used in a sensor, an imaging element, a light-receiving element; an imaging device; a solar battery; a light-emitting element, such as a semiconductor laser element and an LED, which is a current injection type element including the quantum dot ensemble layer as a light-emitting layer; a thin film transistor, and various electronic devices.

### Example 1

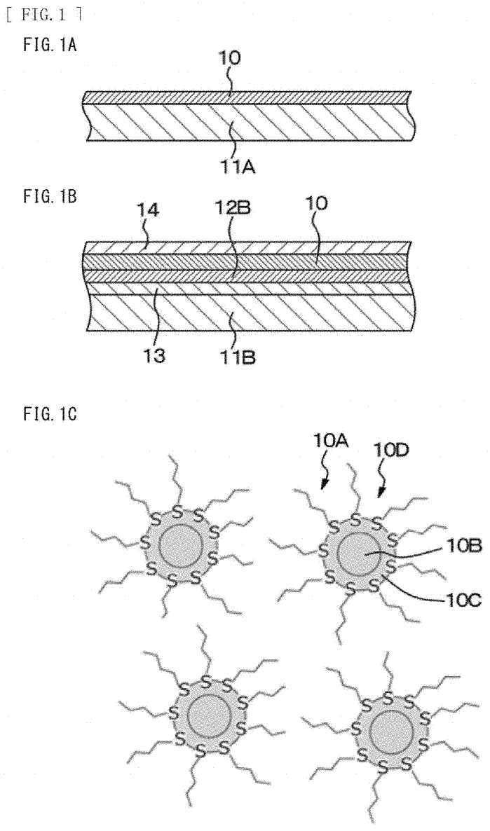

Examples 1 relates to the quantum dot ensemble and the quantum dot ensemble layer of the present disclosure, and the manufacturing method of the quantum dot ensemble according to the first aspect of the present disclosure. FIG. 1C illustrates a conceptual diagram of a quantum dot ensemble layer of Example 1 of Example 1.

The quantum dot ensemble of Example 1 includes a plurality of core-shell quantum dots 10A that each includes a core 10B including a compound semiconductor, and a shell 10C including a compound semiconductor and covering the core 10B, and a ligand (ligand) 10D coordinated to the shell, and the ligand includes an alkane having an average carbon number of 1 or greater and 3 or less and including a chalcogen atom at one end.

In addition, a quantum dot ensemble layer (semiconductor layer) 10 of Example 1 includes a quantum dot ensemble shaped into a layer. The quantum dot ensemble includes a plurality of core-shell quantum dots that each includes a core including a compound semiconductor, and a shell including a compound semiconductor and covering the core, and a ligand (ligand) coordinated to the shell, and the ligand includes an alkane having an average carbon number of 1 or greater and 3 or less and including a chalcogen atom at one end. Here, as illustrated in a schematic partial cross-sectional view in FIG. 1A or FIG. 1B, for example, the quantum dot ensemble layer 10 is shaped (formed) into a layer on a base 11A, or is shaped (formed) into a layer on a functional layer 12B provided on a base 11B.

In Example 1, the shell includes a sulfide, a selenide, or a telluride. Specifically, in Example 1, the shell includes a sulfide, more specifically, ZnS. The core includes CuInSe2, or another material as described later. The alkane includes a chalcogen atom (Group 16 element) at one end, and the chalcogen atom is a part of the chalcogen atoms included in a front surface of the shell. The ligand before being cleaved includes an alkane having a carbon number of 6 or more and including a chalcogen atom (specifically, a sulfur atom in Example 1) at one end, more specifically, dodecanethiol (DDT). The cleaved ligand includes an alkane including, at one end, a chalcogen atom (Group 16 element) that is a part of chalcogen atoms included in the front surface of the shell, and having an average carbon number of 1 or greater and 3 or less, specifically, an alkane having an average carbon number of 2.3 (Example 1A) or 1.7 (Example 1B). An average distance (inter-quantum dot average distance) between a quantum dot and a quantum dot is greater than 0 nm and 1 nm or less, and is specifically as illustrated in Table 1B. A constituent material of the quantum dots has a band gap of 1.0 eV as a bulk of CuInSe2. The average particle diameter of the quantum dots is as illustrated in Table 1A. It is to be noted that “Quantum Dot Coverage” in Table 1B means the number of ligands bonded per unit area (1 nm2) of the front surface of the shell, specifically, a value obtained by dividing (the number of ligands bonded to the shell) by (the surface area of the shell). Note that the ligands indicate the number of non-cleaved ligands (specifically, dodecanethiol) remaining after cleavage, and a small value of the quantum dot coverage indicates that a large amount of dodecanethiol has been cleaved.

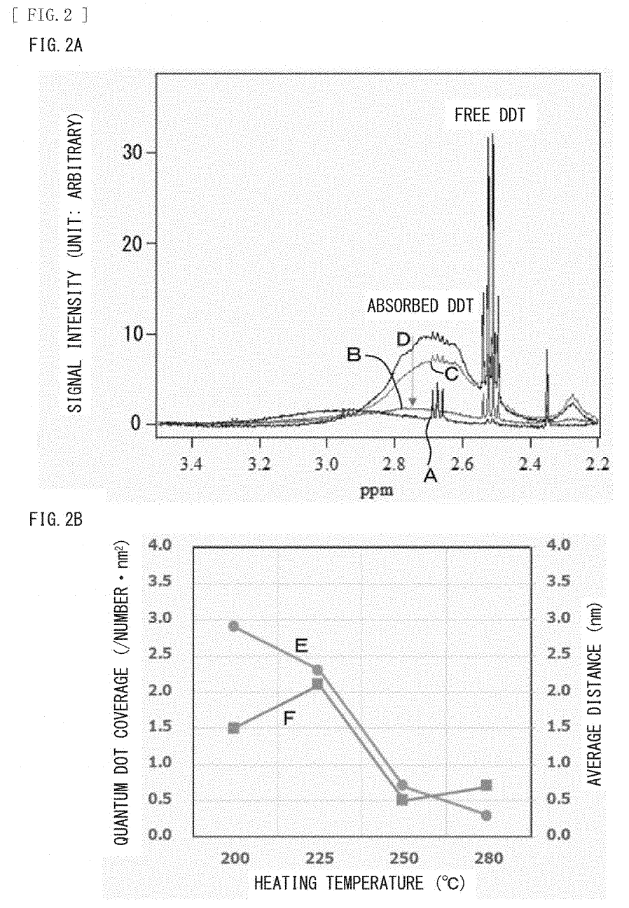

In the following description, the shell includes ZnS, and the core includes CuInSe2. FIG. 2A is a chart illustrating 1H-NMR measurement results. In FIG. 2A, a horizontal axis indicates a chemical shift (ppm), and a vertical axis indicates signal intensity (unit: arbitrary). In FIG. 2A, “A” indicates data at a heating temperature of 280° C. (Example 1A), “B” indicates data at a heating temperature of 250° C. (Example 1B), “C” indicates data at a heating temperature of 225° C. (Comparative Example 1A), and “D” indicates data at a heating temperature of 200° C. (Comparative Example 1B). A peak near 2.5 ppm is a peak based on free DDT, and a peak near 2.7 ppm is a peak based on absorbed DDT. The value of the peak near 2.7 ppm is decreased with an increase in the heating temperature. This shows that cleavage of DDT progresses with an increase in the heating temperature. In addition, it is possible to determine, from the value of this peak, the amount of ligands (cleaved ligands) bonded per unit mass of the quantum dots, and further determine, from the amount of ligands, the number of ligands (cleaved ligands) bonded per unit mass of the quantum dots. When the value of the peak near 2.7 ppm at a heating temperature of 200° C. (a reference sample in which cleavage of absorbed DDT does not progress) in “D” is taken as 1.00, the value of the peak near 2.7 ppm (at a heating temperature of 225° C.) is 0.82, the value of the peak near 2.7 ppm (at a heating temperature of 250° C.) is 0.23, and the value of the peak near 2.7 ppm (at a heating temperature of 280° C.) is 0.13. Accordingly, it can be said that when the value of the peak near 2.7 ppm is 0.3 or less with the value of the peak near 2.7 ppm of DDT (a reference sample in which cleavage of absorbed DDT does not progress) taken as 1.00, DDT is cleaved to a desired state. That is, when, in the ligands of which cleavage does not progress, a peak of hydrogen bonded to carbon adjacent to a chalcogen atom in a ligand absorbed to the shell is taken as 1.00, in cleaved ligands, a peak of hydrogen bonded to carbon adjacent to a chalcogen atom in a ligand absorbed to the shell is 0.3 or less. Results illustrated in Table 1B are graphed in FIG. 2B, where “E” indicates quantum dot coverage and “F” indicates an average distance (inter-quantum dot average distance).

TABLE 1

| | | | Particle | | |
|---|---|---|---|---|---|
| | | | Diameter | Heating | Heating |
| | Core | Shell | (nm) | Temperature | Time |
| Example 1A | CuInSeS2 | ZnS | 8.0 | 280° C. | 30 min. |
| Example I1B | ditto | ditto | 7.6 | 250° C. | 30 min. |
| Comparative | ditto | ditto | 6.0 | 225° C. | 30 min. |
| Example 1A | | | | | |
| Comparative | ditto | ditto | 6.4 | 200° C. | 30 min. |
| Example 1B | | | | | |

| | Average Distance | Quantum Dot Coverage |
|---|---|---|
| Example 1A | 0.7 nm | 0.3/(number nm2) |
| Example 1B | 0.5 nm | 0.7/(number nm2) |
| Comparative | 2.1 nm | 2.3/(number nm2) |
| Example 1A | | |
| Comparative | 1.5 nm | 2.9/(number nm2) |
| Example 1B | | |

In Comparative Example 1A and Comparative Example 1B, the ligands are not cleaved (or are hardly cleaved), the values of quantum dot coverage are large. Meanwhile, the values of quantum dot coverage in Example 1A and Example 1B are smaller than the values of quantum dot coverage in Comparative Example 1A and Comparative Example 1B, which indicates that a large amount of dodecanethiol is cleaved. That is, quantum dot coverage has a smaller value with an increase in the heating temperature, which indicates that a larger amount of DDT is cleaved with an increase in the heating temperature. In addition, it is understood that in Example 1A and Example 1B, the inter-quantum dot average distance becomes shorter by cleavage of ligands, as compared with Comparative Example 1A and Comparative Example 1B in which ligands are not cleaved (or are hardly cleaved).

A manufacturing method of a quantum dot ensemble of Example 1 is the manufacturing method of the quantum dot ensemble of Example 1 described above. In addition, after a core material, a shell material, ligands, and the like that are to be described below are mixed in a solvent, heating is performed to form core-shell quantum dots each including a shell covering a core, coordinate the ligands to the shells, and cleave the ligands.

Hereinafter, description is given of a mixing method (a synthesis method or a preparing method) of mixing the core material, the shell material, and the ligands in the solvent. The following description is given of a synthesis method of five kinds of quantum dots including (CuInSe2/ZnS), (CuInS2/ZnS), (CdSe/ZnS), (InP/ZnS), and (PbS/ZnS) as (core/shell). In any case, a material included in the core and a material included in the shell may form a solid solution.

### (1) Preparation of CuInSe2/ZnS

### [Synthesis of Oleylamine-Coordinated CuInSe2 Nanoparticles]

Into a three-neck flask of 50 milliliters, 99 milligrams (1 millimole) of copper chloride, 221 milligrams (1 millimole) of indium chloride, and 10 milliliters of oleylamine were added, decompression was performed with use of a vacuum pump, the temperature inside the flask was increased to 110° C., and mixing was performed for one hour. Then, pressure was returned to normal pressure under an argon gas atmosphere, and thereafter, the temperature was increased to 180° C., and 5 milliliters of a previously prepared oleylamine solution containing 158 milligrams (2 millimoles) of selenium and 0.35 milliliters (2 millimoles) of diphenylphosphine was quickly added, and mixing was performed at 180° C. for one hour. Next, after natural cooling was performed to room temperature, a reaction solution was equally put into two centrifuge tubes of 50 milliliters, 10 milliliters of hexane and 25 milliliters of ethanol were added into each of the centrifuge tubes, and centrifugation was performed at 7700 G at room temperature for 10 minutes. Thereafter, a supernatant was removed. Then, after 10 milliliters of hexane was added to disperse a precipitate again, 35 milliliters of ethanol was added, and centrifugation was performed at 7700 G at room temperature. After this process was repeated twice, vacuum drying was performed overnight.

### [Synthesis of 1-Dodecanethiol-Coordinated CuInSe2/ZnSn Nanoparticles]

Into a three-neck flask of 50 milliliters, 480 milligrams of CuInSe2 nanoparticles, 245.8 milligrams (1.3 millimoles) of zinc acetate, 1 milliliter of oleylamine, and 20 milliliters of 1-octadecene were added, and reduced-pressure deaeration was performed at 110° C. for one hour with use of a vacuum pump. Then, 5 milliliters of 1-dodecanethiol was added under an argon gas atmosphere, and reduced-pressure deaeration was further performed for 10 minutes with use of the vacuum pump. Next, after pressure was returned to normal pressure under an argon gas atmosphere, for example, the temperature was increased, and mixing was performed at 230° C. for 0.5 hours. This made it possible to coordinate ligands to shells and cleave the ligands. Then, after natural cooling was performed to room temperature, a reaction solution was equally put into two centrifuge tubes of 50 milliliters, 25 milliliters of ethanol was added into each of the centrifuge tubes, and centrifugation was performed at 7700 G at room temperature for 10 minutes. Thereafter, a supernatant was removed. Next, after 10 milliliters of toluene was added to disperse a precipitate again, 35 milliliters of ethanol was added, and centrifugation was performed at 7700 G at room temperature. After this process was repeated twice, vacuum drying was performed overnight. This made it possible to obtain the quantum dot ensemble of Example 1.

### (2) Preparation of CuInS2/ZnS

### [Synthesis of Oleylamine-Coordinated CuInS2 Nanoparticles]

Into a three-neck flask of 50 milliliters, 190 milligrams (1 millimole) of copper iodide, 291 milligram (1 millimole) of indium acetate, 4 milliliters of oleylamine, and 12 milliliters of 1-octadecene were added, and decompression and argon gas purge were repeated three times with use of a vacuum pump. Then, after the temperature inside the flask was increased to 180° C. under an argon gas atmosphere, 2.5 milliliters of a previously prepared oleylamine solution containing 62.1 milligrams (2 millimoles) of sulfur was quickly added, and mixing was performed at 180° C. for 20 minutes. Next, after natural cooling was performed to room temperature, a reaction solution was equally put into two centrifuge tubes of 50 milliliters, 10 milliliters of hexane and 25 milliliters of ethanol were added into each of the centrifuge tubes, and centrifugation was performed at 7700 G at room temperature for 10 minutes. Thereafter, a supernatant was removed. Then, after 10 milliliters of hexane was added to disperse a precipitate again, 35 milliliters of ethanol was added, and centrifugation was performed at 7700 G at room temperature. After this process was repeated twice, vacuum drying was performed overnight.

### [Synthesis of 1-Dodecanethiol-Coordinated CuInS2/ZnS Nanoparticles]

Into a three-neck flask of 50 milliliters, 350 milligrams of CuInS2 nanoparticles, 245.8 milligrams (1.3 millimoles) of zinc acetate, 1 milliliter of oleylamine, and 20 milliliters of 1-octadecene were added, reduced-pressure deaeration was performed at 110° C. for one hour with use of a vacuum pump. Then, 5 milliliters of 1-dodecanethiol was added under an argon gas atmosphere, and reduced-pressure deaeration was further performed for 10 minutes with use of the vacuum pump. Next, after pressure was returned to normal pressure under an argon gas atmosphere, for example, the temperature was increased, and mixing was performed at 230° C. for 0.5 hours. This made it possible to coordinate ligands to shells and cleave the ligands. Then, after natural cooling was performed to room temperature, a reaction solution was equally put into two centrifuge tubes of 50 milliliters, 25 milliliters of ethanol was added into each of the centrifuge tubes, and centrifugation was performed at 7700 G at room temperature for 10 minutes. Thereafter, a supernatant was removed. Next, after 10 milliliters of toluene was added to disperse a precipitate again, 35 milliliters of ethanol was added, and centrifugation was performed at 7700 G at room temperature. After this process was repeated twice, vacuum drying was performed overnight. This made it possible to obtain the quantum dot ensemble of Example 1.

### (3) Preparation of CdSe/ZnS

### [Synthesis of Oleic Acid-Coordinated CdSe Nanoparticles]

Into a three-neck flask of 50 milliliters, 128 milligrams (1 millimole) of cadmium oxide, 4 milliliters of oleic acid, and 20 milliliters of 1-octadecene were added, and decompression and argon gas purge were repeated three times with use of a vacuum pump. Then, after the temperature inside the flask was increased to 300° C. under an argon gas atmosphere, 1 milliliter of a previously prepared trioctylphosphine solution containing 79.0 milligrams (1 millimole) of selenium was quickly added, and mixing was performed at 300° C. for 90 seconds. Next, after natural cooling was performed to room temperature, a reaction solution was equally put into two centrifuge tubes of 50 milliliters, 10 milliliters of hexane and 25 milliliters of ethanol were added into each of the centrifuge tubes, and centrifugation was performed at 7700 G at room temperature for 10 minutes. Thereafter, a supernatant was removed. Then, after 10 milliliters of hexane was added to disperse a precipitate again, 35 milliliters of ethanol was added, and centrifugation was performed at 7700 G at room temperature. After this process was repeated twice, vacuum drying was performed overnight.

### [Synthesis of 1-Dodecanethiol-Coordinated CdSe/ZnS Nanoparticles]

Into a three-neck flask of 50 milliliters, 270 milligrams of CdSe nanoparticles, 245.8 milligrams (1.3 millimoles) of zinc acetate, 1 milliliter of oleylamine, and 20 milliliters of 1-octadecene were added, and reduced-pressure deaeration was performed at 110° C. for one hour with use of a vacuum pump. Then, 5 milliliters of 1-dodecanethiol was added under an argon gas atmosphere, and reduced-pressure deaeration was further performed for 10 minutes with use of the vacuum pump. Next, after pressure was returned to normal pressure under an argon gas atmosphere, for example, the temperature was increased, and mixing was performed at 230° C. for 0.5 hours. This made it possible to coordinate ligands to shells and cleave the ligands. Next, after natural cooling was performed to room temperature, a reaction solution was equally put into two centrifuge tubes of 50 milliliters, 25 milliliters of ethanol was added into each of the centrifuge tubes, and centrifugation was performed at 7700 G at room temperature for 10 minutes. Thereafter, a supernatant was removed. Then, after 10 milliliters of toluene was added to disperse a precipitate again, 35 milliliters of ethanol was added, and centrifugation was performed at 7700 G at room temperature. After this process was repeated twice, vacuum drying was performed overnight. This made it possible to obtain the quantum dot ensemble of Example 1.

### (4) Preparation of InP/ZnS

### [Synthesis of Oleylamine-Coordinated InP Nanoparticles]

Into a three-neck flask of 50 milliliters, 221 milligrams (1 millimole) of indium chloride, 300 milligrams (2.2 millimoles) of zinc chloride, and 5 milliliters of oleylamine were added, and reduced-pressure deaeration was performed at 120° C. with use of a vacuum pump. Then, after the temperature inside the flask was increased to 190° C. under an argon gas atmosphere, 1.0 milliliter (3.6 millimoles) of tris(dimethylamino)phosphine was quickly added, and mixing was performed for 30 minutes. Next, after natural cooling was performed to room temperature, a reaction solution was equally put into two centrifuge tubes of 50 milliliters, 10 milliliters of hexane and 25 milliliters of ethanol were added into each of the centrifuge tubes, and centrifugation was performed at 7700 G at room temperature for 10 minutes. Thereafter, a supernatant was removed. Then, after 10 milliliters of hexane was added to disperse a precipitate again, 35 milliliters of ethanol was added, and centrifugation was performed at 7700 G at room temperature. After this process was repeated twice, vacuum drying was performed overnight.

### [Synthesis of 1-Dodecanethiol-Coordinated InP/ZnS Nanoparticles]

Into a three-neck flask of 50 milliliters, 210 milligrams of InP nanoparticles, 245.8 milligrams (1.3 millimoles) of zinc acetate, 1 milliliter of oleylamine, and 20 milliliters of 1-octadecene were added, and reduced-pressure deaeration was performed at 110° C. for one hour with use of a vacuum pump. Then, 5 milliliters of 1-dodecanethiol was added under an argon gas atmosphere, and reduced-pressure deaeration was further performed for 10 minutes with use of the vacuum pump. Next, after pressure was returned to normal pressure under an argon gas atmosphere, for example, the temperature was increased, and mixing was performed at 230° C. for 0.5 hours. This made it possible to coordinate ligands to shells and cleave the ligands. Then, after natural cooling was performed to room temperature, a reaction solution was equally put into two centrifuge tubes of 50 milliliters, 25 milliliters of ethanol was added into each of the centrifuge tubes, and centrifugation was performed at 7700 G at room temperature for 10 minutes. Thereafter, a supernatant was removed. Next, after 10 milliliters of toluene was added to disperse a precipitate again, 35 milliliters of ethanol was added, and centrifugation was performed at 7700 G at room temperature. After this process was repeated twice, vacuum drying was performed overnight. This made it possible to obtain the quantum dot ensemble of Example 1.

### (5) Preparation of PbS/ZnS

### [Synthesis of Oleic Acid-Coordinated PbS Nanoparticles]

Into a three-neck flask of 50 milliliters, 0.45 grams (2.0 millimoles) of lead oxide, 1.5 milliliters of oleic acid, and 18 milliliters of 1-octadecene were added, and reduced-pressure deaeration was performed at 80° C. for one hour. Then, after the temperature inside the flask was increased to 125° C. under an argon gas atmosphere, a previously prepared solution containing 0.18 milliliters of bistrimethylsilyl sulfide and 10 milliliters of 1-octadecene was quickly added. Thereafter, cooling was performed to 36° C. for 40 minutes or longer. Next, a reaction solution was equally put into two centrifuge tubes of 50 milliliters, 10 milliliters of hexane and 25 milliliters of acetone were added into each of the centrifuge tubes, and centrifugation was performed at 7700 G at room temperature for 10 minutes. Thereafter, a supernatant was removed. Then, after 10 milliliters of toluene was added to disperse a precipitate again, 35 milliliters of acetone was added, and centrifugation was performed at 7700 G at room temperature. After this process was repeated twice, vacuum drying was performed overnight.

[Synthesis of 1-dodecanethiol-coordinated PbS/ZnS Nanoparticles]

Into a three-neck flask of 50 milliliters, 340 milligrams of PbS nanoparticles, 245.8 milligrams (1.3 millimoles) of zinc acetate, 1 milliliter of oleylamine, and 20 milliliters of 1-octadecene were added, and reduced-pressure deaeration was performed at 110° C. for one hour with use of a vacuum pump. Then, 5 milliliters of 1-dodecanethiol was added under an argon gas atmosphere, and reduced-pressure deaeration was further performed for 10 minutes with use of the vacuum pump. Next, after pressure was returned to normal pressure under an argon gas atmosphere, for example, the temperature was increased, and mixing was performed at 230° C. for 0.5 hours. This made it possible to coordinate ligands to shells and cleave the ligands. Then, after natural cooling was performed to room temperature, a reaction solution was equally put into two centrifuge tubes of 50 milliliters, 25 milliliters of ethanol was added into each of the centrifuge tubes, and centrifugation was performed at 7700 G at room temperature for 10 minutes. Thereafter, a supernatant was removed. Next, after 10 milliliters of toluene was added to disperse a precipitate again, 35 milliliters of ethanol was added, and centrifugation was performed at 7700 G at room temperature. After this process was repeated twice, vacuum drying was performed overnight. This made it possible to obtain the quantum dot ensemble of Example 1.

Thereafter, each of thus-obtained various quantum dot ensembles was dispersed in a dispersion medium to obtain a quantum dot dispersion liquid. That is, the quantum dot ensemble of Example 1 further includes a dispersion medium, and the quantum dot ensemble (corresponding to a dispersoid or a disperse phase) is dispersed in the dispersion medium. In other words, a disperse system is configured. It is sufficient if the dispersion medium uses a solvent used in manufacturing of the quantum dot ensemble as it is, and the solvent may be further added to optimize viscosity of the quantum dot dispersion liquid. The content of the quantum dots in 1 milliliter of the quantum dot dispersion liquid was 20 milligrams.

Dispersibility of the quantum dot dispersion liquid was determined from settleability in a case where the quantum dot dispersion liquid is left stand. In the quantum dot dispersion liquid including cleaved ligands, no precipitation of the quantum dot ensemble was recognized, and it was determined that favorable dispersibility was maintained.

As illustrated in a schematic partial cross-sectional view in FIG. 1A, the quantum dot ensemble layer 10 of Example 1 is shaped (formed) into a layer on the base 11A. Specifically, the base 11A includes a resin, more specifically, for example, a polycarbonate resin, an acrylic resin such as PMMA, a PET resin (polyethylene terephthalate resin), a vinyl chloride resin, or a polyamide resin, or includes a glass substrate, and the quantum dot dispersion liquid is formed, cleaned, and dried on the base 11A on the basis of a coating method such as a blade coater method, a slit orifice coater method, or a spin coating method, which makes it possible to obtain the quantum dot ensemble layer 10 having a thickness of 50 nm.

Alternatively, as illustrated in a schematic partial cross-sectional view in FIG. 1B, the quantum dot ensemble layer 10 is shaped (formed) into a layer on the functional layer 12B provided on the base 11B. For formation of the quantum dot ensemble layer 10, it is sufficient if the quantum dot dispersion liquid is applied onto (formed on) the functional layer 12B. Here, the functional layer 12B including ZnO is formed on, for example, a lower electrode 13 including a transparent electrically-conductive material exemplified by ITO. Furthermore, the quantum dot ensemble layer 10 is formed on the functional layer 12B, and an upper electrode 14 including gold (Au) or aluminum (Al) is formed on the quantum dot ensemble layer 10. Further, a solar battery using the quantum dot ensemble layer as a photoelectric conversion layer is thereby configured. Alternatively, the upper electrode 14 including a transparent electrically-conductive material is formed on the quantum dot ensemble layer 10. Further, an imaging element using the quantum dot ensemble layer as a photoelectric conversion layer is thereby configured, and an imaging device including a plurality of such imaging elements is configured.

According to the manufacturing method of the quantum dot ensemble of Example 1, after the core material, the shell material, and the ligands are mixed in a solvent, heating is performed to thereby form core-shell quantum dots each including a shell covering a core, coordinate the ligands to the shells, and cleave the ligands. The ligands are cleaved, which makes it possible to shorten the inter-quantum dot average distance, and consequently achieve higher density of the quantum dot ensemble and the quantum dot ensemble layer. Thus, achieving higher density of the quantum dot ensemble and the quantum dot ensemble layer makes it possible to achieve high mobility. Furthermore, formation of core-shell quantum dots, coordination of ligands to shells, and cleavage of ligands are performed in one process, which makes it difficult to cause contamination by an impurity during manufacturing of the quantum dot ensemble, and makes it possible to achieve simplification of subsequent processes. Thus, it is consequently possible to obtain a quantum dot ensemble, a quantum dot ensemble layer, a sensor, an imaging element, a light-receiving element, a solar battery, a thin film transistor, and various electronic devices that have high performance. It is to be noted that as described in the above-described unexamined patent application publication, in a case where ligand exchange is performed on a substrate, a crack is generated in a coating film; therefore, it is difficult to achieve favorable characteristics. Meanwhile, in Example 1, ligands becomes short in a solution state; therefore, a coating film (quantum dot ensemble layer) becomes resistant to cracks, and it was possible to obtain a quantum dot ensemble layer having favorable characteristics.

### Example 2

Example 2 is a manufacturing method of a quantum dot ensemble according to the second aspect of the present disclosure, and is the manufacturing method of the quantum dot ensemble described in Example 1 in which after core-shell quantum dots are prepared and the quantum dots and ligands are mixed in a solvent, heating is performed to coordinate the ligands to shells and cleave the ligands.

Specifically, after quantum dots and ligands described below are mixed in a solvent, heating is performed to form core-shell quantum dots each including a shell covering a core, coordinate the ligands to the shells, and cleave the ligands. Hereinafter, description is given of a mixing method (a synthesis method or a preparing method) of mixing quantum dots and ligands in a solvent.

### (6) Preparation of CuInSe2/ZnS

### [Synthesis of Oleylamine-Coordinated CuInSe2]

Synthesis of oleylamine-coordinated CuInSe2 nanoparticles in preparation of CuInSe2/ZnS was executed.

### [Synthesis of Oleylamine-Coordinated CuInSe2/ZnS]

Into a three-neck flask of 50 milliliters, 480 milligrams of CuInSe2 nanoparticles and 20 milliliters of 1-octadecene were added, and vacuum deaeration was performed at 150° C. for 30 minutes, and thereafter, temperature was increased to 200° C. under an argon gas atmosphere. Then, a previously prepared solution containing 245.8 milligrams (1.3 millimoles) of zinc acetate and 4 milliliters of oleic acid, and previously prepared solution containing 141.7 milligrams (1.3 millimoles) of sulfur and 0.32 milliliters of tributylphosphine were quickly added, and mixing was performed at 200° C. for 30 minutes. Next, after natural cooling was performed to room temperature, a reaction solution was equally put into two centrifuge tubes of 50 milliliters, 25 milliliters of ethanol was added into each of the centrifuge tubes, and centrifugation was performed at 7700 G at room temperature for 10 minutes. Thereafter, a supernatant was removed. Then, after 10 milliliters of toluene was added to disperse a precipitate again, 35 milliliters of ethanol was added, and centrifugation was performed at 7700 G at room temperature. After this process was repeated twice, vacuum drying was performed overnight.

### [Synthesis of 1-Hexadecane Thiol-Coordinated CuInSe2/ZnS]

Into a three-neck flask of 50 milliliters, 500 milligrams of oleylamine-coordinated CuInSe2/ZnS nanoparticles, 20 milliliters of 1-octadecene, and 10 milliliters of 1-hexadecane thiol were added, and vacuum deaeration was performed at room temperature. Then, temperature was increased to 100° C. under an argon gas atmosphere, and mixing was performed for one hour. Next, after natural cooling was performed to room temperature, a reaction solution was equally put into two centrifuge tubes of 50 milliliters, 25 milliliters of ethanol was added into each of the centrifuge tubes, and centrifugation was performed at 7700 G at room temperature for 10 minutes. Thereafter, a supernatant was removed. Then, after 10 milliliters of toluene was added to disperse a precipitate again, 35 milliliters of ethanol was added, and centrifugation was performed at 7700 G at room temperature. After this process was repeated twice, vacuum drying was performed overnight.

### [Heat Treatment of 1-Hexadecane Thiol-Coordinated CuInSe2/ZnS]

Into a three-neck flask of 50 milliliters, 500 milligrams of 1-hexadecane thiol-coordinated CuInSe2/ZnS nanoparticles and 20 milliliters of 1-octadecene were added, and vacuum deaeration was performed at room temperature. Then, temperature was increased under an argon gas atmosphere, and mixing was performed at 230° C. for 0.5 hours, for example. This made it possible to coordinate ligands to shells and cleave the ligands. Next, after natural cooling was performed until room temperature, a reaction solution was equally put into two centrifuge tubes of 50 milliliters, 25 milliliters of ethanol was added into each of the centrifuge tubes, and centrifugation was performed at 7700 G at room temperature for 10 minutes. Thereafter, a supernatant was removed. Then, after 10 milliliters of toluene was added to disperse a precipitate again, 35 milliliters of ethanol was added, and centrifugation was performed at 7700 G at room temperature. After this process was repeated twice, vacuum drying was performed overnight. This made it possible to obtain the quantum dot ensemble of Example 2.

Thereafter, the thus-obtained quantum dot ensemble was dispersed in a dispersion medium to obtain a quantum dot dispersion liquid. That is, as with the quantum dot ensemble of Example 1, the quantum dot ensemble of Example 2 further includes a dispersion medium, and the quantum dot ensemble (corresponding to a dispersoid or a disperse phase) is dispersed in the dispersion medium. In other words, a disperse system is configured. It is sufficient if the dispersion medium uses a solvent used in manufacturing of the quantum dot ensemble as it is, and the solvent may be further added to optimize viscosity of the quantum dot dispersion liquid. The content of the quantum dots in 1 milliliter of the quantum dot dispersion liquid was 20 milligrams.

The quantum dot ensemble layer 10 of Example 2 is shaped into a layer on a base or a functional layer. Specifically, the quantum dot ensemble layer 10 of Example 2 is similar to that described in Example 1.

According to the manufacturing method of the quantum dot ensemble of Example 2, after the quantum dots and ligands are mixed in a solvent, heating is performed to coordinate the ligands to the shells and cleave the ligands, which makes it possible to shorten the inter-quantum dot average distance. This consequently makes it possible to achieve higher density of the quantum dot ensemble and the quantum dot ensemble layer.

### Example 3

Example 3 is an application of the quantum dot ensemble layer described in Example 1 and Example 2, and relates to an imaging device of the present disclosure. Hereinafter, general description is first given of the imaging device of the present disclosure, and description is then given of an imaging device of Example 3.

The imaging device of the present disclosure includes a plurality of imaging elements arranged, and each of the imaging elements includes a stacked structure in which a first electrode, a photoelectric conversion layer including a quantum dot ensemble layer, and a second electrode are stacked. The quantum dot ensemble layer includes the quantum dot ensemble layer described in Example 1.

Furthermore, in a preferred mode of the imaging element included in the imaging device of the present disclosure, a photoelectric converter further includes a charge accumulation electrode that is disposed at a distance from the first electrode and is disposed to be opposed to a photoelectric conversion layer with an insulating layer interposed therebetween. It is to be noted that such an imaging element is referred to as an “imaging element including the charge accumulation electrode” for the sake of convenience. That is, in a preferred mode of the imaging device of the present disclosure, a plurality of imaging elements each including the charge accumulation electrode is included.

In the imaging element including the charge accumulation electrode, the charge accumulation electrode is provided that is disposed at a distance from the first electrode and disposed to be opposed to the photoelectric conversion layer with the insulating layer interposed therebetween; therefore, it is possible to accumulate electric charge in the photoelectric conversion layer when the photoelectric converter is irradiated with light and photoelectric conversion is performed in the photoelectric converter. It is therefore possible to completely deplete a charge accumulation section and eliminate the electric charge when exposure is started. As a result, it is possible to suppress the occurrence of a phenomenon that kTC noise becomes greater and random noise deteriorates to cause reduction in quality of captured images.

The imaging element including the charge accumulation electrode may further include a semiconductor substrate, and a mode may be adopted in which the photoelectric converter is disposed above the semiconductor substrate. It is to be noted that the first electrode, the charge accumulation electrode, the second electrode, and various electrodes are coupled to a drive circuit (to be described later).

The second electrode positioned on light incident side may be shared by a plurality of imaging elements. That is, the second electrode may be a so-called solid electrode. The photoelectric conversion layer may be shared by a plurality of imaging elements, that is, one photoelectric conversion layer may be formed for a plurality of imaging elements. Alternatively, one photoelectric conversion layer may be provided for each imaging element. An oxide semiconductor layer (to be described later) is preferably provided for each imaging element; however, in some cases, the oxide semiconductor layer may be shared by a plurality of imaging elements. That is, one oxide semiconductor layer shared by a plurality of imaging elements may be formed.

Further, in the imaging element including the charge accumulation electrode that includes the various preferred modes and configurations described above, a mode may be adopted in which the first electrode extends in an opening provided in the insulating layer and is coupled to the photoelectric conversion layer. Alternatively, a mode may be adopted in which the photoelectric conversion layer extends in the opening provided in the insulating layer and is coupled to the first electrode.

Hereinafter, description is given of a case where a potential to be applied to the first electrode is higher than a potential to be applied to the second electrode; however, in a case where the potential to be applied to the first electrode is lower than the potential to be applied to the second electrode, it is sufficient if high/low relation of potentials to be applied to various electrodes is inverted. In the following description, reference numerals representing the potentials to be applied to various electrodes are illustrated in the following Table 2.

TABLE 2

| | Charge | Charge |
|---|---|---|
| | Accumulation | Transfer |
| | Period | Period |
| First Electrode | V11 | V12 |
| Second Electrode | V21 | V22 |
| Charge Accumulation Electrode | V31 | V32 |
| Transfer Control Electrode | V41 | V42 |

In the imaging element including the charge accumulation electrode that includes the various preferred modes and configurations described above, a configuration may be adopted in which the imaging element further includes a controller provided in the semiconductor substrate and including a drive circuit; the first electrode and the charge accumulation electrode are coupled to the drive circuit; during a charge accumulation period, from the drive circuit, a potential V11 is applied to the first electrode, a potential V31 is applied to the charge accumulation electrode, and electric charge is accumulated in the photoelectric conversion layer; and during a charge transfer period, from the drive circuit, a potential V12 is applied to the first electrode, a potential V32 is applied to the charge accumulation electrode, and the electric charge accumulated in the photoelectric conversion layer is read out to the controller via the first electrode. Note that V31≥V11 and V32≤V12 hold true.

In the imaging element including the charge accumulation electrode that includes the various preferred modes and configurations described above, a mode may be adopted in which the imaging element further includes, between the first electrode and the charge accumulation electrode, a transfer control electrode (charge transfer electrode) that is disposed at a distance from the first electrode and the charge accumulation electrodes and disposed to be opposed to the photoelectric conversion layer with the insulating layer interposed therebetween. It is to be noted that the imaging element including the charge accumulation electrode in such a mode is referred to as an “imaging element including the transfer control electrode” for the sake of convenience.

In addition, a configuration may be adopted in which the imaging element including the transfer control electrode further includes a controller provided in the semiconductor substrate and including a drive circuit; the first electrode, the charge accumulation electrode, and the transfer control electrode are coupled to the drive circuit; during a charge accumulation period, from the drive circuit, a potential V11 is applied to the first electrode, a potential V31 is applied to the charge accumulation electrode, a potential V41 is applied to the transfer control electrode, and electric charge is accumulated in the photoelectric conversion layer; and during a charge transfer period, from the drive circuit, a potential V12 is applied to the first electrode, a potential V32 is applied to the charge accumulation electrode, a potential V42 is applied to the transfer control electrode, and the electric charge accumulated in the photoelectric conversion layer is read out to the controller via the first electrode. Note that V31>V41 and V32≤V42≤V12 hold true.

In the imaging element including the charge accumulation electrode that includes the various preferred modes and configurations described above, a configuration may be adopted in which at least a floating diffusion layer and an amplification transistor included in the controller are provided in the semiconductor substrate, and the first electrode is coupled to the floating diffusion layer and a gate section of the amplification transistor. Then, in this case, furthermore, a configuration may be adopted in which a reset transistor and a selection transistor included in the controller are further provided in the semiconductor substrate, the floating diffusion layer is coupled to one of source/drain regions of the reset transistor, and one of source/drain regions of the amplification transistor is coupled to one of source/drain regions of the selection transistor, and another one of the source/drain regions of the selection transistor is coupled to a signal line.

Furthermore, in the imaging element including the charge accumulation electrode that includes the various preferred modes and configurations described above, a mode may be adopted in which the charge accumulation electrode is larger in size than the first electrode. It is preferable, but not limited, that 4≤s1′/s1 be satisfied, where s1′ is the area of the charge accumulation electrode, and s1 is the area of the first electrode.

Further, in the imaging element including the charge accumulation electrode that includes the various preferred modes and configuration described above, a mode may be adopted in which light enters from side of the second electrode, and a light-blocking layer is formed on the light incident side closer to the second electrode. Alternatively, a mode may be adopted in which light enters from the side of the second electrode, and no light enters the first electrode (in some cases, light enters neither of the first electrode and the transfer control electrode). In addition, in this case, a configuration may be adopted in which the light-blocking layer is formed on the light incident side closer to the second electrode and above the first electrode (in some cases, the first electrode and the transfer control electrode). Alternatively, a configuration may be adopted in which an on-chip microlens is provided above the charge accumulation electrode and the second electrode, and light entering the on-chip microlens is condensed onto the charge accumulation electrode. Here, the light-blocking layer may be disposed above a surface of the second electrode on the light incident side, or may be disposed on the surface of the second electrode on the light incident side. The light-blocking layer may be formed in the second electrode in some cases. Examples of a material included in light-blocking layer include chromium (Cr), copper (Cu), aluminum (Al), tungsten (W), and non-light-transmitting resins (e.g., a polyimide resin).

Specific examples of the imaging element including the charge accumulation electrode may include an imaging element that has sensitivity to blue light and includes a photoelectric conversion layer or a photoelectric converter that absorbs blue light (light of 425 nm to 495 nm), an imaging element that has sensitivity to green light and includes a photoelectric conversion layer or a photoelectric converter that absorbs green light (light of 495 nm to 570 nm); and an imaging element an imaging element that has sensitivity to red light and includes a photoelectric conversion layer or a photoelectric converter that absorbs red light (light at 620 nm to 750 nm).

In the imaging element of the present disclosure, the first electrode is formed on, for example, an interlayer insulating layer provided on the semiconductor substrate. The imaging element formed on the semiconductor substrate may be of a back illuminated type or a front illuminated type.

The photoelectric conversion layer in the imaging element includes the quantum dot ensemble layer of the present disclosure. It is possible to form the quantum dot ensemble layer on the basis of any of the methods described in Example 1 and Example 2. The functional layer includes an insulating layer or an oxide semiconductor layer. That is, for formation of the photoelectric conversion layer including the quantum dot ensemble layer, for example, it is sufficient if the quantum dot dispersion liquid is applied onto the insulting layer or the oxide semiconductor layer serving as the functional layer, and dried.

Alternatively, the photoelectric conversion layer may have a stacked layer configuration of a lower semiconductor layer and an upper photoelectric conversion layer. Providing the lower semiconductor layer in such a manner makes it possible to prevent recombination during charge accumulation, makes it possible to further increase efficiency of transfer of the electric charge accumulated in the photoelectric conversion layer to the first electrode, and makes it possible to suppress generation of a dark current. A material included in the upper photoelectric conversion layer may be selected from various materials included in the photoelectric conversion layer described above. Meanwhile, as a material included in the lower semiconductor layer, it is preferable to use a material having a large band gap value (e.g., a band gap value of 3.0 eV or more) and having higher mobility than the material included in the photoelectric conversion layer. Specific examples thereof may include an oxide semiconductor material; transition metal dichalcogenide; silicon carbide; diamond; graphene; carbon nanotubes; and an organic semiconductor material such as a condensed polycyclic hydrocarbon compound and a condensed heterocyclic compound. Alternatively, examples of the material included in the lower semiconductor layer may include a material having an ionization potential larger than the ionization potential of the material included in the photoelectric conversion layer in a case where electric charge to be accumulated is an electron, and may include a material having electron affinity smaller than electron affinity of the material included in the photoelectric conversion layer in a case where electric charge to be accumulated is a hole. Alternatively, the impurity concentration in the material included in the lower semiconductor layer is preferably 1×10¹⁸ cm⁻³ or less. The lower semiconductor layer may have a single-layer configuration or a multilayer configuration. In addition, a material included in the lower semiconductor layer positioned above the charge accumulation electrode and a material included in the lower semiconductor layer positioned above the first electrode may be different.

Examples of the oxide semiconductor material included in the lower semiconductor layer may include indium oxide, gallium oxide, zinc oxide, tin oxide, a material including at least one kind selected from these oxides, and a material obtained by adding a dopant to any of these materials. Specific examples thereof may include IGZO, ITZO, IWZO, IWO, ZTO, an ITO-SiOx-based material, GZO, IGO, ZnSnO₃, AlZnO, GaZnO, and InZnO. In addition, specific examples thereof may include materials including CuI, InSbO₄, ZnMgO, CuInO₂, MgIn₂O₄, CdO, and the like. However, the oxide semiconductor material is not limited to these materials. The lower semiconductor layer including the oxide semiconductor material (hereinafter referred to as an “oxide semiconductor layer” in some cases) may have a single-layer configuration or a multilayer configuration. A material included in the oxide semiconductor layer positioned above the charge accumulation electrode and a material included in the oxide semiconductor layer positioned above the first electrode may be different.

A mode may be adopted in which the thickness of the oxide semiconductor layer is 1×10⁻⁸ m to 1.5×10⁻⁷ m, preferably 2×10⁻⁸ m to 1.0×10⁻⁷ m, more preferably 3×10⁻⁸ m to 1.0×10⁻⁷ m. The impurity concentration in the oxide semiconductor material is preferably 1×10¹⁸ cm⁻³ or less. In addition, the carrier concentration of the oxide semiconductor material layer is preferably less than 1×10¹⁶/cm³, and mobility of the material included in the oxide semiconductor layer is preferably 10 cm²Ns or more.

It is possible to form the oxide semiconductor layer on the basis of, for example, a sputtering method. Specifically, as a sputtering device, it is possible to use a parallel flat plate sputtering device, a DC magnetron sputtering device, or an RF sputtering device, and as a process gas, it is possible to use an argon (Ar) gas.

The oxide semiconductor layer preferably has a light transmittance of 65% or more for light having a wavelength of 400 nm to 660 nm. In addition, the charge accumulation electrode also preferably has a light transmittance of 65% or more for light having a wavelength of 400 nm to 660 nm. The charge accumulation electrode preferably has a sheet resistance of 3×10 Ω/square to 1×10³ Ω/square.

It is possible to configure a single-plate color imaging device by the imaging device of the present disclosure. In addition, a pixel region in which a plurality of imaging elements in the imaging device of the present disclosure are arranged includes a plurality of pixels systematically arranged in a two-dimensional array. The pixel region typically includes: an effective pixel region in which light is actually received to generate signal charge through photoelectric conversion, and the signal charge is amplified and read out to the drive circuit; and a black reference pixel region (also called an optical black pixel region (OPB)) for outputting optical black serving as a black level reference. The black reference pixel region is typically disposed on an outer periphery of the effective pixel region.

In the imaging device, using a color filter layer makes it possible to ease demands on spectral characteristics of blue, green, and red, and provides high mass productivity. Examples of arrangement of the imaging elements in the imaging device include an interline arrangement, a G stripe RB checkered arrangement, a G stripe RB full checkered arrangement, a checkered complementary color arrangement, a stripe arrangement, a diagonal stripe arrangement, a primary color difference arrangement, a field color difference sequential arrangement, a frame color difference sequential arrangement, a MOS arrangement, an improved MOS arrangement, a frame interleave arrangement, and a field interleave arrangement, as well as a Bayer arrangement. Here, one imaging element constitutes one pixel (or subpixel).

Examples of the color filter layer (wavelength selection means) include a filter layer that transmits not only red, green, and blue, but also specific wavelengths, such as cyan, magenta, and yellow, in some cases. It is possible for the color filter layer to be configured not only by an organic material-based color filter layer using an organic compound such as a pigment or a dye, but also by a thin film including an inorganic material such as a photonic crystal, a wavelength selection element based on application of plasmon (color filter layer having a conductor lattice structure with a lattice-like hole structure in a conductive thin film; see, for example, Japanese Unexamined Patent Application Publication No. 2008-177191), or amorphous silicon.

In the imaging element including the charge accumulation electrode that includes the various preferred modes and configurations described above, irradiation with light is performed, photoelectric conversion is performed in the photoelectric conversion layer, and holes and electrons are subjected to carrier separation. Then, an electrode from which the holes are extracted is an anode, and an electrode from which the electrons are extracted is a cathode. A mode may be adopted in which the first electrode constitutes the anode, and the second electrode constitutes the cathode, or a mode may be adopted in which the first electrode constitutes the cathode, and the second electrode constitutes the anode.

A configuration may be adopted in which the first electrode, the charge accumulation electrode, the transfer control electrode, and the second electrode include transparent electrically-conductive materials. The first electrode, the charge accumulation electrode, and the transfer control electrode are collectively referred to as a “first electrode and the like” in some cases. Alternatively, a configuration may be adopted in which the second electrode includes a transparent electrically-conductive material, and the first electrode and the like include a metal material. In this case, specifically, a configuration may be adopted in which the second electrode positioned on the light incident side includes a transparent electrically-conductive material, and the first electrode and the like include, for example, Al—Nd (alloy of aluminum and neodymium) or ASC (alloy of aluminum, samarium, and copper). An electrode including a transparent electrically-conductive material is referred to as a “transparent electrode” in some cases. Here, it is desirable that the band-gap energy of the transparent electrically-conductive material be 2.5 eV or more, preferably, 3.1 eV or more. Examples of the transparent electrically-conductive material included in the transparent electrode may include electrically-conductive metal oxides. Specific examples thereof may include indium oxide, indium-tin oxide (ITO, Indium Tin Oxide, including Sn-doped In₂O₃, crystalline ITO, and amorphous ITO), indium-zinc oxide (IZO, Indium Zinc Oxide) in which indium is added as a dopant to zinc oxide, indium-gallium oxide (IGO) in which indium is added as a dopant to gallium oxide, indium-gallium-zinc oxide (IGZO, In—GaZnO₄) in which indium and gallium are added as dopants to zinc oxide, indium-tin-zinc oxide (ITZO) in which indium and tin are added as dopants to zinc oxide, IFO (F-doped In₂O₃), tin oxide (SnO₂), ATO (Sb-doped SnO₂), FTO (F-doped SnO₂), zinc oxide (including ZnO doped with another element), aluminum-zinc oxide (AZO) in which aluminum is added as a dopant to zinc oxide, gallium-zinc oxide (GZO) in which gallium is added as a dopant to zinc oxide, titanium oxide (TiO₂), niobium-titanium oxide (TNO) in which niobium is added as a dopant to titanium oxide, antimony oxide, CuI, InSbO₄, ZnMgO, CuInO₂, MgIn₂O₄, CdO, ZnSnO₃, spinel oxide, and an oxide having YbFe₂O₄ structure. Alternatively, the transparent electrode may include gallium oxide, titanium oxide, niobium oxide, nickel oxide, or the like as a mother layer. The thickness of the transparent electrode may be 2×10⁻⁸ m to 2×10⁻⁷ m, preferably, 3×10⁻⁸ m to 1×10⁻⁷ m.

Alternatively, in a case where transparency is not necessary, it is preferred to use an electrically-conductive material with a high work function (e.g., ϕ=4.5 eV to 5.5 eV) as an electrically-conductive material included in the anode which functions as an electrode for extracting holes. Specific examples of such an electrically-conductive material may include gold (Au), silver (Ag), chromium (Cr), nickel (Ni), palladium (Pd), platinum (Pt), iron (Fe), iridium (Ir), germanium (Ge), osmium (Os), rhenium (Re), and tellurium (Te). In contrast, it is preferred to use an electrically-conductive material with a low work function (e.g., ϕ=3.5 eV to 4.5 eV) as an electrically-conductive material included in the cathode which functions as an electrode for extracting electrons. Specific examples of such an electrically-conductive material may include alkali metals (e.g., Li, Na, K, and the like) and fluorides or oxides thereof, alkaline earth metals (e.g., Mg, Ca, and the like) and fluorides or oxides thereof, aluminum (Al), zinc (Zn), tin (Sn), thallium (Tl), a sodium-potassium alloy, an aluminum-lithium alloy, a magnesium-silver alloy, indium, rare earth metals such as ytterbium, and alloys thereof. Alternatively, examples of the material included in the anode or the cathode may include electrically-conductive materials, including metals such as platinum (Pt), gold (Au), palladium (Pd), chromium (Cr), nickel (Ni), aluminum (Al), silver (Ag), tantalum (Ta), tungsten. (W), copper (Cu), titanium (Ti), indium (In), tin (Sn), iron (Fe), cobalt (Co), and molybdenum (Mo), alloys including these metal elements, electrically-conductive particles including these metals, electrically-conductive particles of alloys including these metals, polysilicon including impurities, carbon-based materials, oxide semiconductors, carbon nanotubes, graphene, and the like, and stacked structures of layers including these elements. Further examples of the material included in the anode or the cathode may include organic materials (electrically-conductive polymers) such as poly(3,4-ethylenedioxythiophene)/polystyrenesulfonic acid [PEDOT/PSS]. In addition, these electrically-conductive materials may be mixed with a binder (polymer) into a paste or an ink, and the paste or the ink may be cured and used as an electrode.

A dry method or a wet method is usable as a film formation method for the first electrode or the like and the second electrode (cathode or anode). Examples of the dry method may include a physical vapor deposition method (PVD method) and a chemical vapor deposition method (CVD method). Examples of the film formation method using the principle of the PVD method may include a vacuum deposition method using resistance heating or radio frequency heating, an EB (electron beam) deposition method, various sputtering methods (a magnetron sputtering method, an RF-DC coupled bias sputtering method, an ECR sputtering method, a facing-target sputtering method, and a high frequency sputtering method), an ion plating method, a laser ablation method, a molecular beam epitaxy method, and a laser transfer method. In addition, examples of the CVD method may include a plasma CVD method, a thermal CVD method, an organic metal (MO) CVD method, and an optical CVD method. Meanwhile, examples of the wet method may include methods such as an electrolytic plating method and an electroless plating method, a spin coating method, an ink jet printing method, a spray coating method, a stamping method, a micro contact printing method, a flexographic printing method, an offset printing method, a gravure printing method, and a dipping method. Examples of a patterning method may include chemical etching, including shadow mask, laser transfer, photolithography, and the like, and physical etching by ultraviolet light, laser, or the like. As a planarization technique for the first electrode and the like and the second electrode, a laser planarization method, a reflow method, a CMP (Chemical Mechanical Polishing) method, or the like may be used.

Examples of a material included in the insulating layer may include not only inorganic insulating materials exemplified by metal oxide high dielectric insulating materials including: silicon oxide-based materials; silicon nitride (SiNY); and aluminum oxide (Al₂O₃), but also organic insulating materials (organic polymers) exemplified by polymethyl methacrylate (PMMA); polyvinyl phenol (PVP); polyvinyl alcohol (PVA); polyimide; polycarbonate (PC); polyethylene terephthalate (PET); polystyrene; silanol derivatives (silane coupling agents) including N-2 (aminoethyl) 3-aminopropyltrimethoxysilane (AEAPTMS), 3-mercaptopropyltrimethoxysilane (MPTMS), octadecyltrichlorosilane (OTS) and the like; novolac-type phenolic resins; fluorine-based resins; straight-chain hydrocarbons having a functional group being able to bond to a control electrode at one end, including octadecanethiol, dodecyl isocyanate and the like, and combinations thereof. Examples of the silicon oxide-based materials may include silicon oxide (SiOx), BPSG, PSG, BSG, AsSG, PbSG, silicon oxynitride (SiON), SOG (spin-on-glass), and low dielectric constant insulating materials (e.g., polyaryl ether, cycloperfluorocarbon polymers and benzocyclobutene, cyclic fluororesins, polytetrafluoroethylene, fluorinated aryl ether, fluorinated polyimide, amorphous carbon, and organic SOG). The insulating layer may have a single-layer configuration, or a configuration including a plurality of layers (e.g., two layers) stacked. In the latter case, an insulating layer/lower layer may be formed at least on the charge accumulation electrode and in a region between the charge accumulation electrode and the first electrode. A planarization process may be performed on the insulating layer/lower layer to allow the insulating layer/lower layer to remain at least in the region between the charge accumulation electrode and the first electrode. It is sufficient if an insulating layer/upper layer is formed on the remaining insulating layer/lower layer and the charge accumulation electrode. This makes it possible to planarize the insulating layer with reliability. It is sufficient if materials included in various interlayer insulating layers, insulating material films, insulating material layers, protection layers, and insulating films are appropriately selected from these materials.

The configurations and structures of the floating diffusion layer, the amplification transistor, the reset transistor, and the selection transistor included in the controller may be similar to the configurations and structures of existing floating diffusion layers, amplification transistors, reset transistors, and selection transistors. The drive circuit may also have a known configuration and structure.

While the first electrode is coupled to the floating diffusion layer and the gate section of the amplification transistor, it is sufficient if a contact hole section is formed for the coupling of the first electrode to the floating diffusion layer and the gate section of the amplification transistor. Examples of a material for forming the contact hole section may include polysilicon doped with impurities, high melting point metals such as tungsten, Ti, Pt, Pd, Cu, TiW, TiN, TiNW, WSi2, and MoSi2, metal silicides, and a stacked structure of layers including these materials (e.g., Ti/TiN/W).

A first carrier blocking layer may be provided between an organic photoelectric conversion layer and the first electrode, and a second carrier blocking layer may be provided between the organic photoelectric conversion layer and the second electrode. In addition, a first charge injection layer may be provided between the first carrier blocking layer and the first electrode, and a second charge injection layer may be provided between the second carrier blocking layer and the second electrode. For example, examples of the materials included in the electron injection layers may include alkali metals, including lithium (Li), sodium (Na), and potassium (K), fluorides or oxides thereof, alkaline earth metals, including magnesium (Mg) and calcium (Ca), and fluorides or oxides thereof.

For the imaging element or the imaging device, a mode may be adopted in which one on-chip microlens is disposed above one imaging element. Alternatively, a mode may be adopted in which two imaging elements constitute an imaging element block, and one on-chip microlens is disposed above the imaging element block. In addition, a light-blocking layer may be provided on the imaging element, and a drive circuit and wiring lines for driving the imaging element may be provided. A shutter for controlling incidence of light on the imaging element may be disposed as necessary, and an optical cut filter may be provided according to the purpose of the imaging device.

For example, in a case of stacking the imaging device and a readout integrated circuit (ROIC), the stacking may be performed by laying a driving substrate having the readout integrated circuit and a coupling section including copper (Cu) formed thereon and an imaging element having a coupling section formed thereon over each other such that their respective coupling sections come into contact with each other, and joining the coupling sections. The coupling sections may be joined to each other using a solder bump or the like.

Further, a driving method for driving the imaging device may be a driving method of the imaging device repeating the steps of: draining electric charge in the first electrodes out of systems all at once while accumulating electric charge in the photoelectric conversion layers in all of the imaging elements; and thereafter, transferring the electric charge accumulated in the photoelectric conversion layers all at once to the first electrodes in all of the imaging elements, and after completion of the transferring, sequentially reading out the electric charge transferred to the first electrodes in the respective imaging elements.

In such a driving method of the imaging device, each imaging element has a structure in which light having entered from the side of the second electrode does not enter the first electrode and, in all of the imaging elements, electric charge in the first electrodes is drained out of the systems all at once while accumulating electric charge in the lower semiconductor layers. This makes it possible to perform resetting of the first electrodes with reliability in all of the imaging elements simultaneously. Thereafter, in all of the imaging elements, the electric charge accumulated in the lower semiconductor layers is transferred all at once to the first electrodes, and after completion of the transferring, the electric charge transferred to the first electrodes is sequentially read out in the respective imaging elements. It is therefore possible to achieve a so-called global shutter function easily.

Detailed description of the imaging element and the imaging device of Example 3 is given below. It is to be noted that in the imaging device of Example 3, examples of arrangement of the plurality of imaging elements may include a Bayer arrangement. Color filter layers for performing blue, green, and red spectral separation are disposed on the light incident side of each of the imaging elements as necessary.

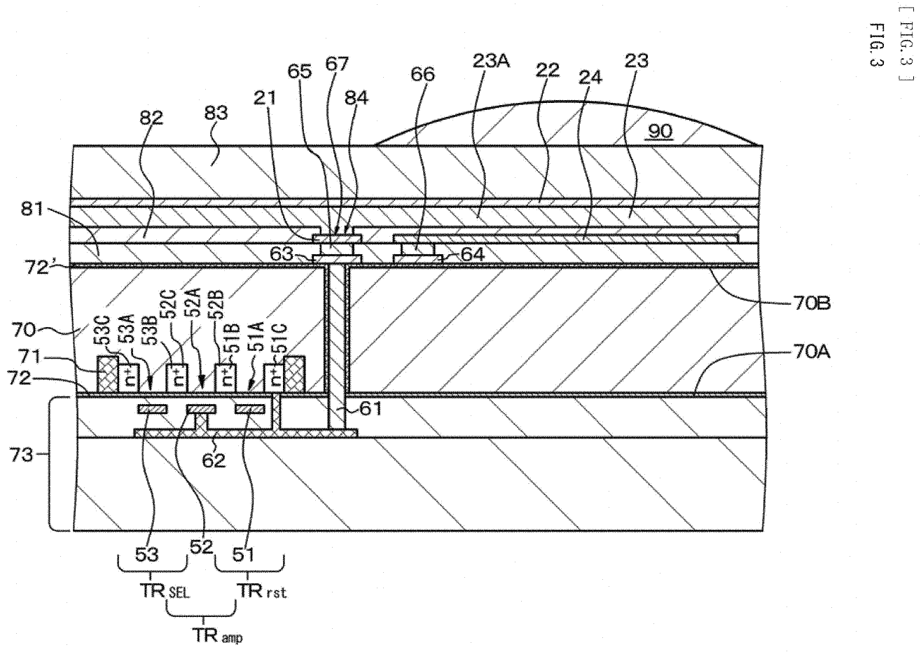

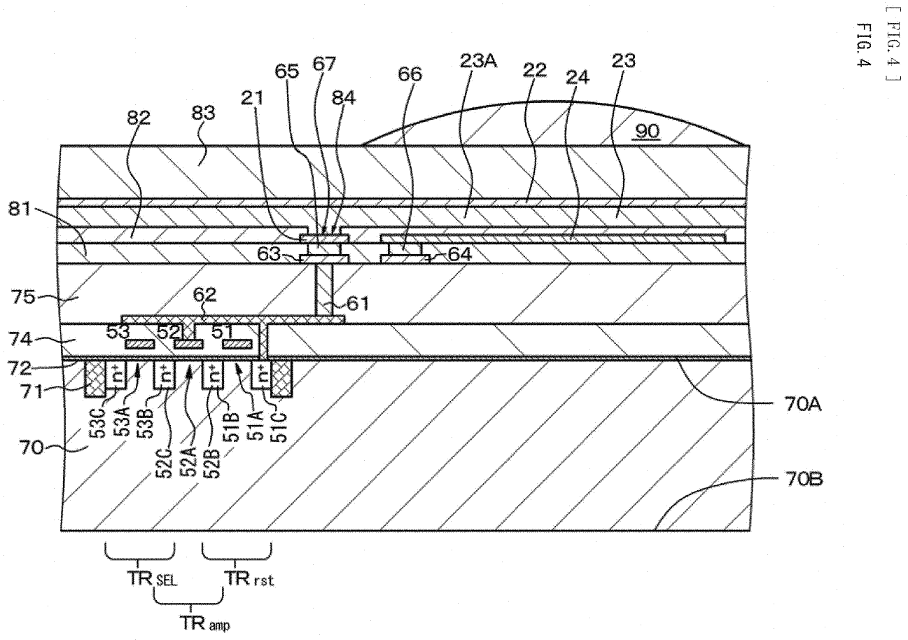

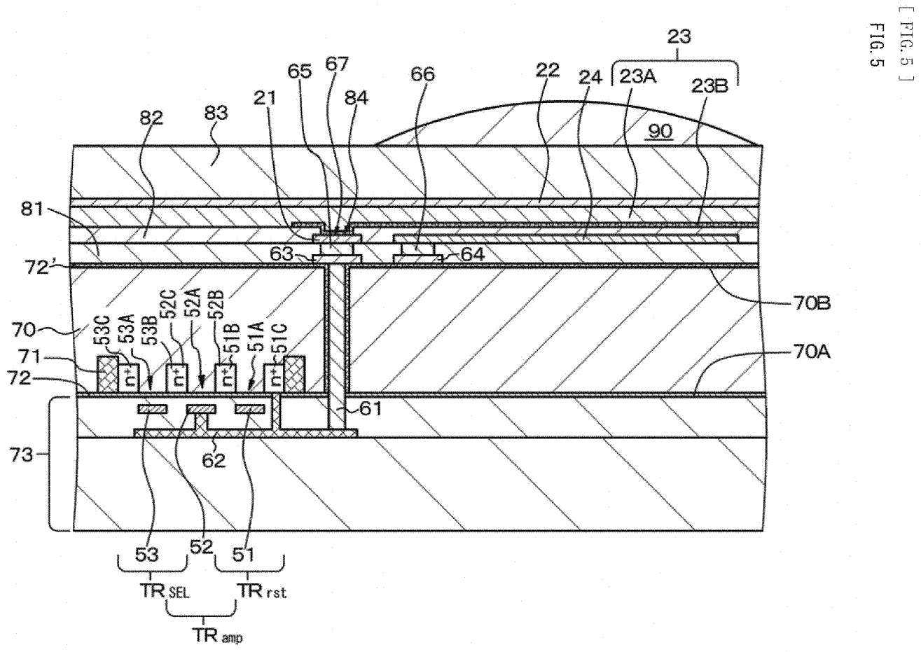

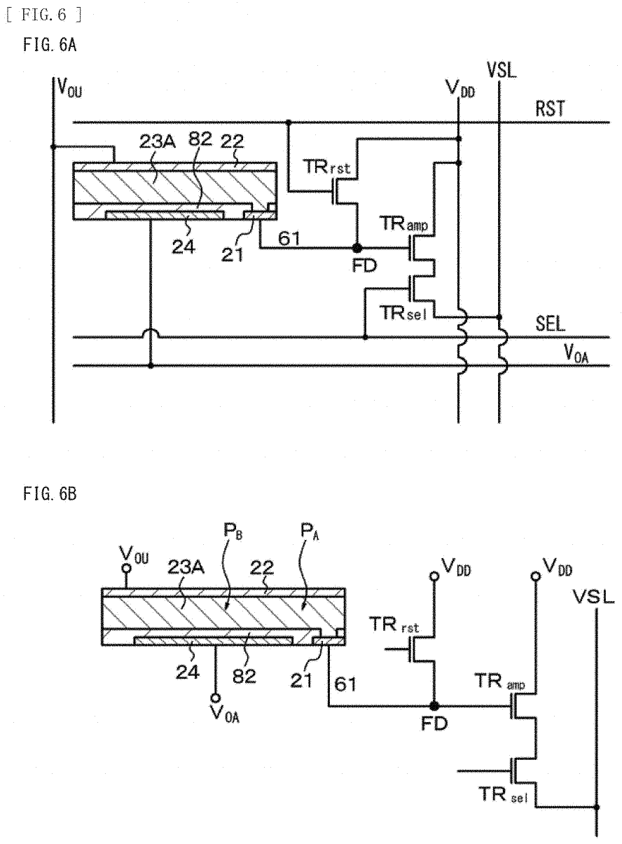

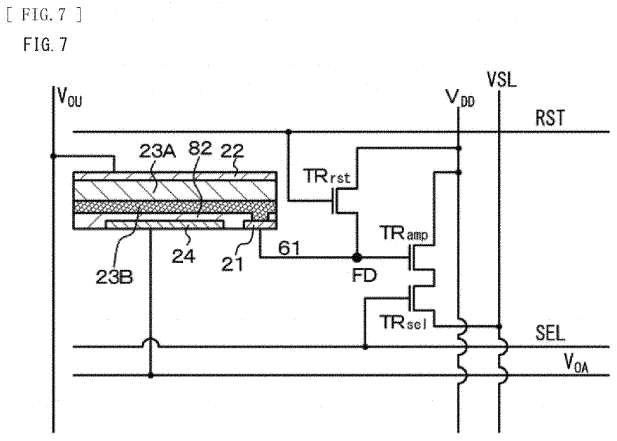

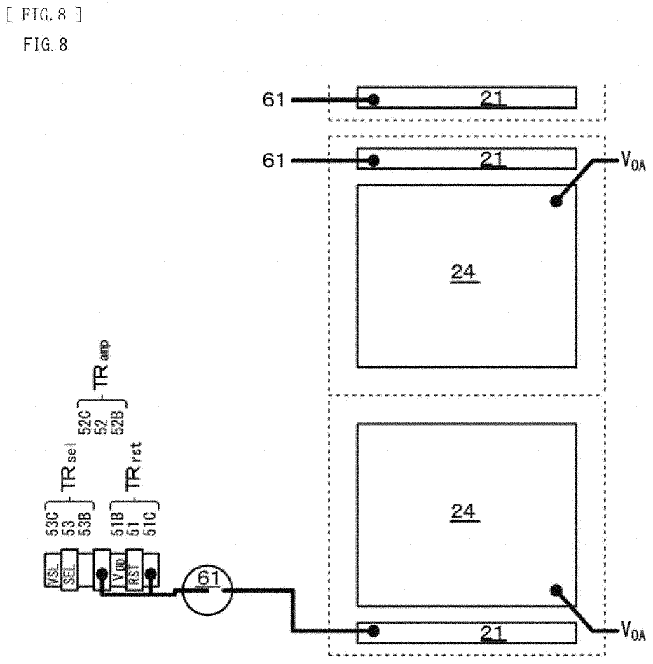

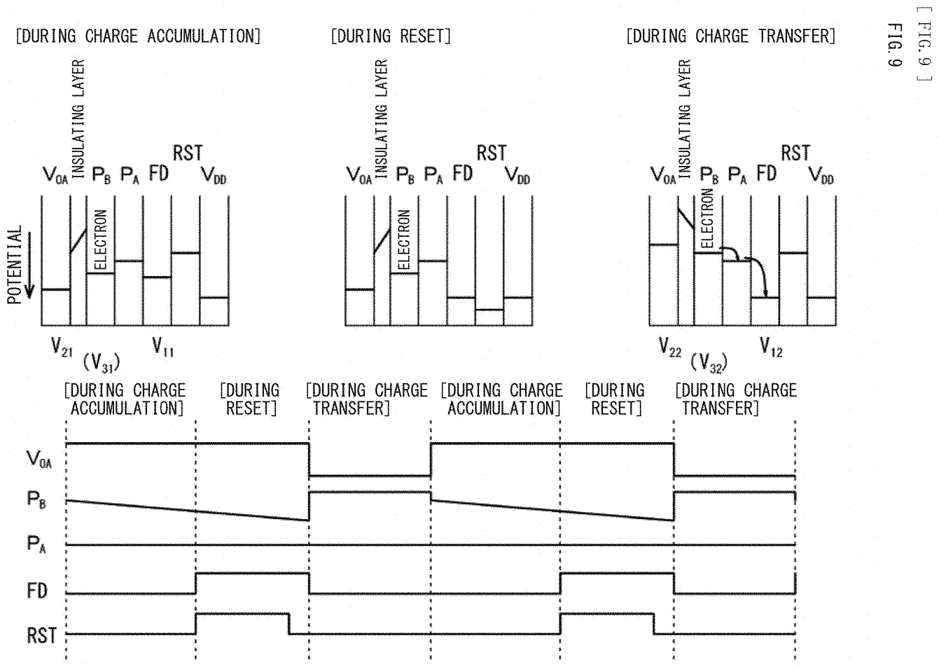

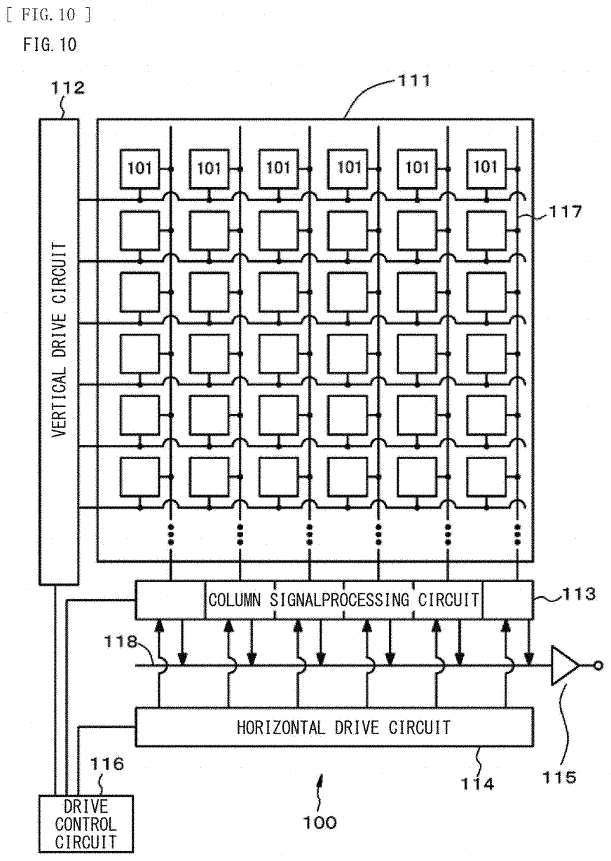

FIG. 3 illustrates a schematic partial cross-sectional view of the back illuminated type imaging element of Example 3. FIG. 4 illustrates a schematic partial cross-sectional view of Modification Example-1 of the front illuminated type imaging element of Example 3. FIG. 5 illustrates a schematic partial cross-sectional view of Modification Example-2. In addition, FIG. 6A illustrates an equivalent circuit diagram of the imaging element of Example 3. FIG. 7 illustrates an equivalent circuit diagram of Modification Example-2 of the imaging element of Example 3. FIG. 9 schematically illustrates a state of a potential in each part during an operation of the imaging element of Example 3. FIG. 6B is an equivalent circuit diagram of the imaging element of Example 3 for describing each part in FIG. 9. FIG. 10 is a conceptual diagram of the imaging device of Example 3. Furthermore, FIG. 8 is a schematic layout diagram of the first electrode and the charge accumulation electrode, and transistors included in the controller that are included in the imaging element of Example 3. It is to be noted that for simplification of drawings, various imaging element constituent elements positioned below an interlayer insulating layer 81 may be collectively denoted by the reference numeral 91 for the sake of convenience in order to simplify the drawings.

The imaging element of Example 3 specifically includes a first electrode 21, a charge accumulation electrode 24 disposed at a distance from the first electrode 21, a photoelectric converter 23 formed in contact with the first electrode 21 and above the charge accumulation electrode 24 with an insulating layer 82 interposed therebetween, and a second electrode 22 formed on the photoelectric converter 23. The photoelectric converter 23 includes a photoelectric conversion layer 23A including the quantum dot ensemble layer described in Examples 1 and 2. For formation of the photoelectric conversion layer 23A including the quantum dot ensemble layer, for example, it is sufficient if a quantum dot dispersion liquid is applied onto the insulating layer 82 serving as a functional layer, and dried.

The imaging element of Example 3 further includes a semiconductor substrate (more specifically, a silicon semiconductor layer) 70, and the photoelectric converter is disposed above the semiconductor substrate 70. In addition, the imaging element of Example 3 further includes a controller that is provided in the semiconductor substrate 70 and includes a drive circuit to which the first electrode 21 and the second electrode 22 are coupled. Here, a light incident surface of the semiconductor substrate 70 is defined as above, and opposite side of the semiconductor substrate 70 is defined as below. A wiring layer 62 including a plurality of wiring lines is provided below the semiconductor substrate 70.

At least a floating diffusion layer FD and an amplification transistor TRamp included in the controller are provided in the semiconductor substrate 70, and the first electrode 21 is coupled to the floating diffusion layer FD and a gate section of the amplification transistor TRamp. A reset transistor TRrst and a selection transistor TRsel included in the controller are further provided in the semiconductor substrate 70. The floating diffusion layer FD is coupled to one of source/drain regions of the reset transistor TRrst. Another one of source/drain regions of the amplification transistor TRamp is coupled to one of source/drain regions of the selection transistor TRsel. Another one of the source/drain regions of the selection transistor TRsel is coupled to a signal line VSL. The amplification transistor TRamp, the reset transistor TRrst, and the selection transistor TRsel constitute the drive circuit.

In the imaging element of Example 3, the first electrode 21 and the charge accumulation electrode 24 are formed at a distance from each other on the interlayer insulating layer 81. The interlayer insulating layer 81 and the charge accumulation electrode 24 are covered with the insulating layer 82. The photoelectric conversion layer 23A is formed on the insulating layer 82, and the second electrode 22 is formed on the photoelectric conversion layer 23A. A protection layer 83 is formed over the entire surface inclusive of the second electrode 22, and an on-chip microlens 90 is provided on the protection layer 83. A color filter layer may be provided or may not be provided in accordance with specifications of the imaging device. The first electrode 21, the charge accumulation electrode 24, and the second electrode 22 each include a transparent electrode including, for example, ITO (work function: about 4.4 eV). As described above, the photoelectric conversion layer 23A includes the quantum dot ensemble layer described in Examples 1 and 2. The interlayer insulating layer 81, the insulating layer 82, and the protection layer 83 each include a known insulating material (e.g., SiO2 or SiN). The photoelectric conversion layer 23A and the first electrode 21 are coupled to each other by a coupling section 67 provided at the insulating layer 82. The photoelectric conversion layer 23A extends in the coupling section 67. That is, the photoelectric conversion layer 23A extends in an opening 84 provided in the insulating layer 82, and is coupled to the first electrode 21.

It is possible to form the quantum dot ensemble layer on the basis of the method described in any of Examples 1 and 2. The insulating layer 82 serves as a base. Alternatively, an oxide semiconductor layer 23B to be described later serves as a functional layer.

The charge accumulation electrode 24 is coupled to the drive circuit. Specifically, the charge accumulation electrode 24 is coupled to a vertical drive circuit 112 included in the drive circuit, via a coupling hole 66, a pad section 64, and a wiring line VOA provided in the interlayer insulating layer 81.

The charge accumulation electrode 24 is larger in size than the first electrode 21. It is preferable, but not limited, that 4≤s1′/s1 be satisfied, where s1′ is the area of the charge accumulation electrode 24, and s1 is the area of the first electrode 21. In Example 3, s1′/s1=8 holds true, although not limited thereto.

Element separation regions 71 are formed on side of a first surface (front surface) 70A of the semiconductor substrate 70, and an insulating material film 72 is formed on the first surface 70A of the semiconductor substrate 70. Further, on side of the first surface of the semiconductor substrate 70, the reset transistor TRrst, the amplification transistor TRamp, and the selection transistor TRsel included in the controller of the imaging element are provided, and further, the floating diffusion layer FD is provided.

The reset transistor TRrst includes a gate section 51, a channel formation region 51A, and source/drain regions 51B and 51C. The gate section 51 of the reset transistor TRrst is coupled to a reset line RST, the one source/drain region 51C of the reset transistor TRrst also serves as the floating diffusion layer FD, and another source/drain region 51B is coupled to a power supply VDD.

The first electrode 21 is coupled to the one source/drain region 51C (floating diffusion layer FD) of the reset transistor TRᵣₛₜ, via a coupling hole 65 and a pad section 63 provided in the interlayer insulating layer 81, and a contact hole section 61 formed in the semiconductor substrate 70 and an interlayer insulating layer 73, and the wiring layer 62 formed in the interlayer insulating layer 73. The interlayer insulating layer 73 is formed on the front surface (front surface) 70A of the semiconductor substrate 70, and, although not illustrated, a wiring line is formed over a plurality of layers in the interlayer insulating layer 73. An insulating film 72′ is formed on a back surface 70B of the semiconductor substrate 70 and an inner wall of the contact hole section 61. It is to be noted that the reference numeral 74 and the reference numeral 75 in FIG. 4 each denote an interlayer insulating layer.

The amplification transistor TRamp includes a gate section 52, a channel formation region 52A, and source/drain regions 52B and 52C. The gate section 52 is coupled to the first electrode 21 and the one source/drain region 51C (floating diffusion layer FD) of the reset transistor TRrst via the wiring layer 62. In addition, the one source/drain region 52B is coupled to the power supply VDD.

The selection transistor TRsel includes a gate section 53, a channel formation region 53A, and source/drain regions 53B and 53C. The gate section 53 is coupled to a selection line SEL. In addition, the one source/drain region 53B shares a region with another source/drain region 52C included in the amplification transistor TRamp, and another source/drain region 53C is coupled to a signal line (data output line) VSL (117).

The reset line RST, the selection line SEL are coupled to the vertical drive circuit 112 included in the drive circuit, and the signal line (data output line) VSL is coupled to a column signal processing circuit 113 included in the drive circuit.

Hereinafter, description is given of an operation of the imaging element including the charge accumulation electrode of Example 3 with reference to FIGS. 9 and 6B. Here, the potential of the first electrode 21 is higher than the potential of the second electrode 22. That is, for example, the first electrode 21 is set to a positive potential and the second electrode 22 is set to a negative potential. Electrons generated by photoelectric conversion in the photoelectric converter 23 are read out to the floating diffusion layer. The same applies also to other Examples. It is to be noted that in a mode in which the first electrode 21 is set to a negative potential and the second electrode 22 is set to a positive potential, and holes generated by photoelectric conversion in the photoelectric converter 23 are read out to the floating diffusion layer, it is sufficient if high/low relation of potentials described below is inverted.

Reference numerals used in FIGS. 9, 16, and 17 are as follows.

PA: Potential at a point PA in a region of the photoelectric converter 23 opposed to a region positioned intermediate between the charge accumulation electrode 24 or a transfer control electrode (charge transfer electrode) 25 and the first electrode 21

PB: Potential at a point PB in a region of the photoelectric converter 23 opposed to the charge accumulation electrode 24

PC: Potential at a point PC in a region of the photoelectric converter 23 opposed to the transfer control electrode (charge transfer electrode 25

FD: Potential at the floating diffusion layer FD

VOA: Potential at the charge accumulation electrode 24

VOT: Potential at the transfer control electrode (charge transfer electrode) 25

RST: Potential at the gate section 51 of the reset transistor TRrst

VDD: Potential of the power supply

VSL: Signal line (data output line)

TRrst: Reset transistor TRrst

TRamp: Amplification transistor TRamp

TRsel: Selection transistor TRsel

During a charge accumulation period, from the drive circuit, the potential V11 is applied to the first electrode 21 and the potential V31 is applied to the charge accumulation electrode 24. Light having entered the photoelectric conversion layer 23A is photoelectrically converted in the photoelectric conversion layer 23A. Holes generated by photoelectric conversion are sent from the second electrode 22 to the drive circuit via a wiring line VOU. Meanwhile, because the potential of the first electrode 21 is higher than the potential of the second electrode 22, that is, because a positive potential is to be applied to the first electrode 21 and a negative potential is to be applied to the second electrode 22, V31≥V11 holds true, and preferably, V31>V11 holds true. This causes electrons generated by the photoelectric conversion to be attracted to the charge accumulation electrode 24, and to remain in a region of the photoelectric conversion layer 23A, opposed to the charge accumulation electrode 24. That is, electric charge is accumulated in the photoelectric conversion layer 23A. Because V31>V11 holds true, the electrons generated inside of the photoelectric conversion layer 23A would not move toward the first electrode 21. With the passage of time of photoelectric conversion, the potential in the region of the photoelectric conversion layer 23A, opposed to the charge accumulation electrode 24 has a more negative value.

A reset operation is performed later in the charge accumulation period. This resets the potential of the floating diffusion layer FD, and the potential of the floating diffusion layer FD shifts to the potential VDD of the power supply.

After completion of the reset operation, the electric charge is read out. That is, during a charge transfer period, from the drive circuit, the potential V12 is applied to the first electrode 21 and the potential V32 is applied to the charge accumulation electrode 24. Here, V32<V12 holds true. This causes the electrons remaining in the region of the photoelectric conversion layer 23A, opposed to the charge accumulation electrode 24 to be read out to the first electrode 21, and further to the floating diffusion layer FD. That is, the electric charge accumulated in the photoelectric conversion layer 23A is read out to the controller.

This completes the series of operations including the charge accumulation, the reset operation, and the charge transfer.

The operations of the amplification transistor TRamp and the selection transistor TRsel after the electrons are read out to the floating diffusion layer FD are the same as the operations of existing ones of these transistors. Reset noise of the floating diffusion layer FD is removable through a correlated double sampling (CDS, Correlated Double Sampling) process in a similar manner to the existing techniques.

As described above, in Example 3, the charge accumulation electrode is provided that is disposed at a distance from the first electrode and disposed to be opposed to the photoelectric conversion layer with the insulating layer interposed therebetween. Thus, when the photoelectric conversion layer is irradiated with light and photoelectric conversion is performed in the photoelectric conversion layer, a kind of capacitor is formed by the photoelectric conversion layer, the insulating layer, and the charge accumulation electrode, which makes it possible to accumulate electric charge in the photoelectric conversion layer. It is therefore possible to completely deplete the charge accumulation section and eliminate the electric charge when exposure is started. As a result, it is possible to suppress the occurrence of a phenomenon in which kTC noise becomes greater and random noise deteriorates to cause reduction in quality of the captured images. In addition, because it is possible to reset all of the pixels all at once, a so-called global shutter function is achievable.

In Modification Example-2 of the imaging element of Example 3, the photoelectric converter includes the upper photoelectric conversion layer (photoelectric conversion layer 23A) and the lower semiconductor layer (oxide semiconductor layer) 23B from the side of the second electrode. For example, providing the oxide semiconductor layer 23B makes it possible to prevent recombination during charge accumulation, and makes it possible to further increase efficiency of transfer of the electric charge accumulated in the photoelectric conversion layer 23A. Further, it is possible to temporarily hold the electric charge generated in the photoelectric conversion layer 21A to thereby control the timing of transfer and the like. It is also possible to suppress generation of a dark current.

That is, in Modification Example-2 of the imaging element of Example 3, the first electrode 21 and the charge accumulation electrode 24 are formed at a distance from each other on the interlayer insulating layer 81. The interlayer insulating layer 81 and the charge accumulation electrode 24 are covered with the insulating layer 82. The oxide semiconductor layer 23B and the photoelectric conversion layer 23A are formed on the insulating layer 82, and the second electrode 22 is formed on the photoelectric conversion layer 23A. The protection layer 83 is formed over the entire surface inclusive of the second electrode 22, and the on-chip microlens 90 is provided on the protection layer 83. No color filter layer is provided; however, a color filter layer may be provided in accordance with specifications of the imaging device. The first electrode 21, the charge accumulation electrode 24, and the second electrode 22 each include a transparent electrode including, for example, ITO (work function: about 4.4 eV). The interlayer insulating layer 81, the insulating layer 82, and the protection layer 83 include a known insulating material (e.g., SiO2 or SiN). The oxide semiconductor layer 23B and the first electrode 21 are coupled to each other by the coupling section 67 provided at the insulating layer 82. The oxide semiconductor layer 23B extends in the coupling section 67. That is, the oxide semiconductor layer 23B extends in the opening 84 provided in the insulating layer 82, and is coupled to the first electrode 21.

FIG. 10 illustrates a conceptual diagram of the imaging device of Example 3. An imaging device 100 of Example 3 includes an imaging region 111 in which imaging elements 101 are arranged in a two-dimensional array, and, as drive circuits (peripheral circuits) thereof, the vertical drive circuit 112, the column signal processing circuit 113, a horizontal drive circuit 114, an output circuit 115, a drive control circuit 116, and the like. Needless to say, these circuits may include known circuits, or may be configured using other circuit configurations (e.g., various circuits used in existing CCD imaging devices or CMOS imaging devices). In FIG. 10, the representation of the reference numeral “101” for the imaging elements 101 is made in only one row.

On the basis of a vertical synchronization signal, a horizontal synchronization signal, and a master clock, the drive control circuit 116 generates a clock signal and a control signal serving as a reference for operations of the vertical drive circuit 112, the column signal processing circuit 113, and the horizontal drive circuit 114. Then, the clock signal and the control signal thus generated are inputted to the vertical drive circuit 112, the column signal processing circuit 113, and the horizontal drive circuit 114.

The vertical drive circuit 112 includes, for example, a shift register, and selectively scans the imaging elements 101 in the imaging region 111 sequentially in a vertical direction row by row. Then, a pixel signal (image signal) based on a current (signal) generated corresponding to the amount of light received at each imaging element 101 is sent to the column signal processing circuit 113 via the signal line (data output line) 117 or VSL.

The column signal processing circuit 113 is disposed, for example, for each column of the imaging elements 101, and performs signal processing, including noise removal and signal amplification, on the image signals outputted from one row of the imaging elements 101 for each imaging element in accordance with a signal from a black reference pixel (although not illustrated, formed around the effective pixel region). At an output stage of the column signal processing circuit 113, a horizontal selection switch (not illustrated) is provided to be coupled between the output stage and a horizontal signal line 118.

The horizontal drive circuit 114 includes, for example, a shift register, and sequentially outputs horizontal scan pulses to sequentially select each one of the column signal processing circuits 113, thereby outputting a signal from each of the column signal processing circuits 113 to the horizontal signal line 118.

The output circuit 115 performs signal processing on the signals sequentially supplied from the respective column signal processing circuits 113 through the horizontal signal line 118, and outputs the processed signals.

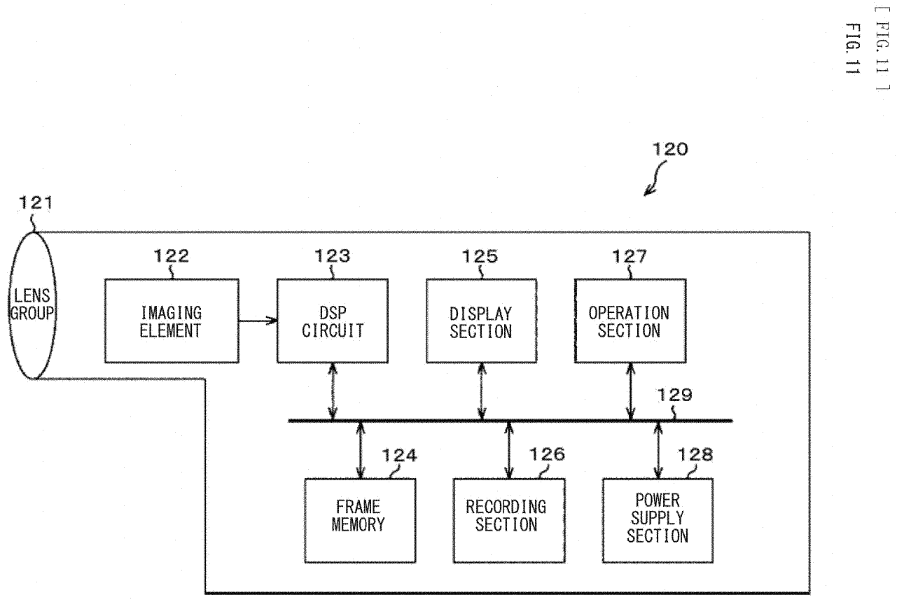

FIG. 11 is a block diagram illustrating an example of a configuration example of an imaging device. Here, an imaging device 120 includes a video camera, a digital still camera, or the like. The imaging device 120 includes a lens group 121, an imaging element 122, a DSP circuit 123, a frame memory 124, a display section 125, a recording section 126, an operation section 127, and a power supply section 128. The DSP circuit 123, the frame memory 124, the display section 125, the recording section 126, the operation section 127, and the power supply section 128 are coupled to each other via a bus line 129.

The lens group 121 captures incident light (image light) from a subject and forms an image on an imaging plane of the imaging element 122. The imaging element 122 includes the imaging element described above. The imaging element 122 converts a light amount of the incident light formed as an image on the imaging plane by the lens group 121 into an electric signal on a per-pixel basis and supplies the electric signal as a pixel signal to the DSP circuit 123. The DSP circuit 103 performs predetermined image processing on the pixel signal supplied from the imaging element 122, and supplies the pixel signals having been subjected to the image processing to the frame memory 124 on a per-frame basis, and the pixel signals are temporarily stored in the frame memory 124.

The display section 125 includes, for example, a panel-type display device such as a liquid crystal panel or an organic EL (Electro Luminescence) panel, and displays an image on the basis of each frame of the pixel signals temporarily stored in the frame memory 124. The recording section 126 includes a DVD (Digital Versatile Disk), a flash memory, or the like, and reads out and records each frame unit of the pixel signals temporarily stored in the frame memory 124. The operation section 127 issues an operation command for various functions of the imaging device 120 under a user's operation. The power supply section 128 supplies power to the DSP circuit 123, the frame memory 124, the display section 125, the recording section 126, and the operation section 127 as appropriate.

It is sufficient if an electronic apparatus includes the imaging device described above in an image capturing section, and examples of the electronic apparatus may include a portable terminal device having an imaging function and a copying machine including the imaging device 120 in an image capturing section (image readout section), in addition to the imaging device 120.

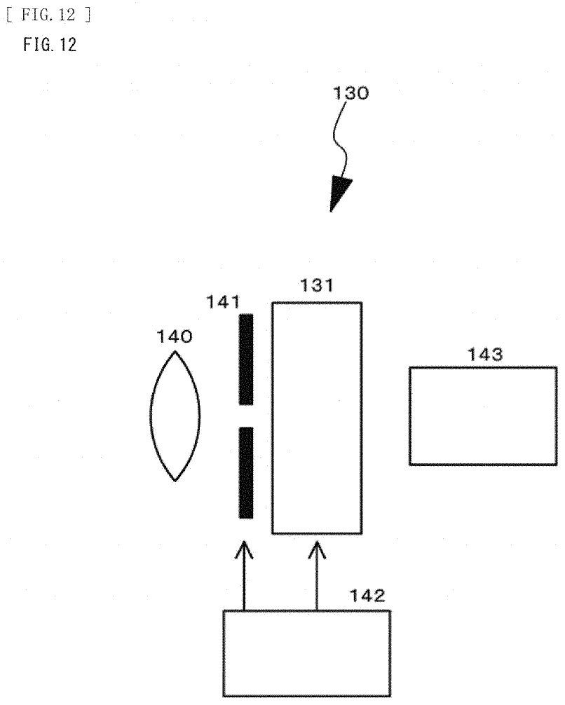

In addition, FIG. 12 illustrates, as a conceptual diagram, an example of using a solid-state imaging device 131 including the imaging element of the present disclosure in an electronic apparatus (camera) 130. The electronic apparatus 130 includes the solid-state imaging device 131, an optical lens 140, a shutter device 141, a drive circuit 142, and a signal processing circuit 143. The optical lens 140 focuses image light (incident light) from a subject to form an image on an imaging plane of the solid-state imaging device 131. This causes signal charge to be accumulated in the solid-state imaging device 131 for a predetermined period of time. The shutter device 141 controls a period during which the solid-state imaging device 131 is irradiated with light and a period during which the light is blocked. The drive circuit 142 supplies drive signals for controlling a transfer operation, and the like of the solid-state imaging device 131 and a shutter operation of the shutter device 141. Signal transfer in the solid-state imaging device 131 is performed in accordance with the drive signals (timing signals) supplied from the drive circuit 142. The signal processing circuit 143 performs various kinds of signal processing. An image signal having been subjected to the signal processing is stored in a storage medium such as a memory, or is outputted to a monitor. In such an electronic apparatus 130, the solid-state imaging device 131 is able to achieve miniaturization of pixel size and improvement in transfer efficiency, thus making it possible to provide the electronic apparatus 130 with improved pixel characteristics. Examples of the electronic apparatus 130 to which the solid-state imaging device 131 is applicable are not limited to a camera, but include imaging devices such as a digital still camera and a camera module for a mobile apparatus such as a mobile phone.

Examples of the imaging element of Example 3, or Example 4 to be described later may include a CCD element, a CMOS image sensor, a CIS (Contact Image Sensor), and a signal amplification image sensor of a CMD (Charge Modulation Device) type. The imaging element may be included in, for example, a digital still camera, a video camera, a camcorder, a monitoring camera, an on-vehicle camera (vehicle-mounted camera), a smartphone camera, a user interface camera for games, a biometric authentication camera, and the like.

### Example 4

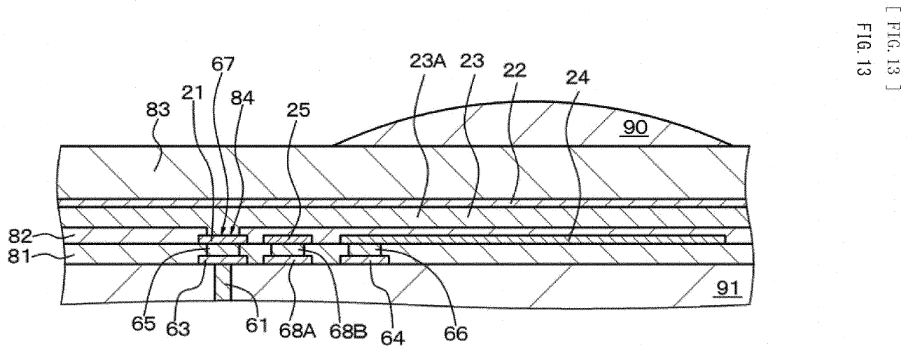

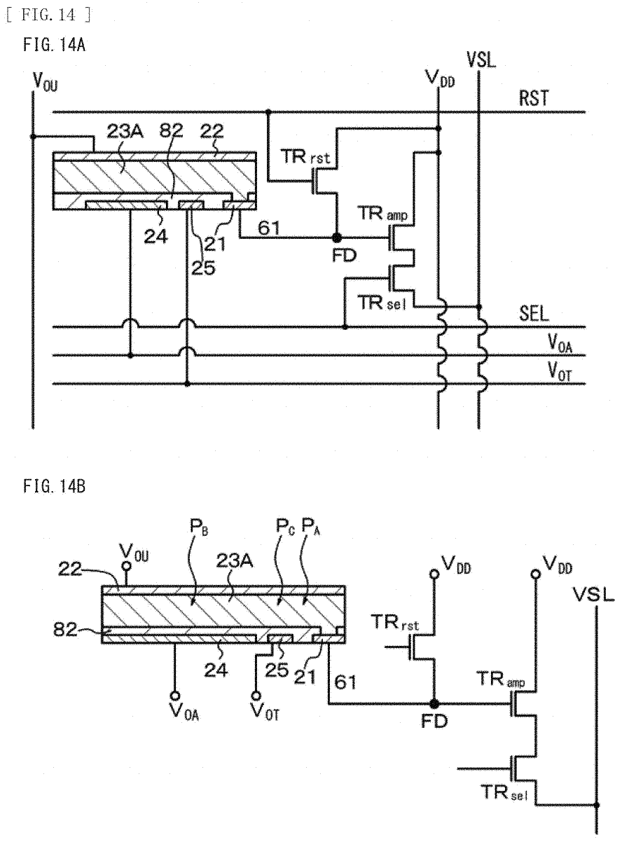

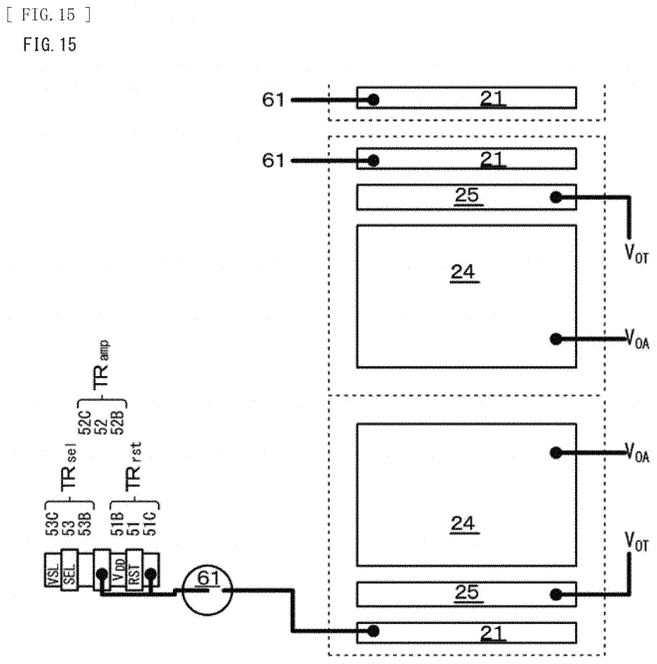

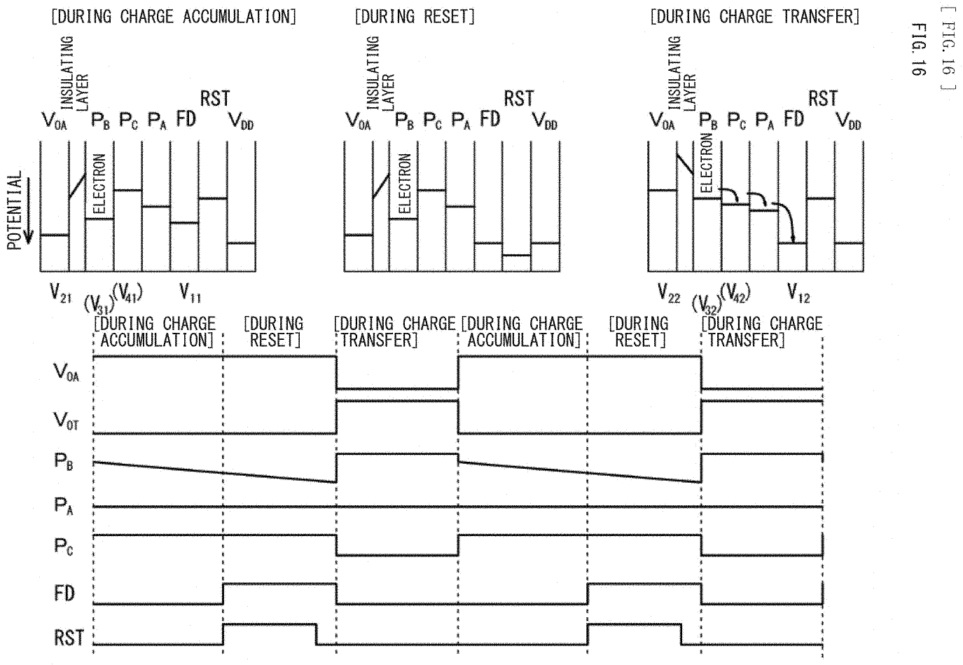

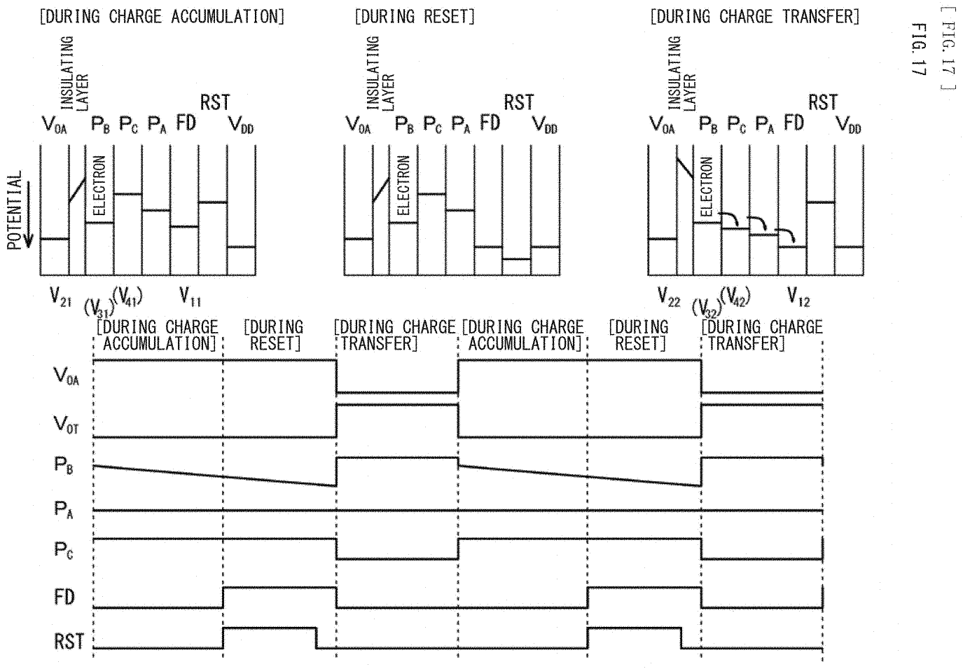

Example 4 is a modification of Example 3, and relates to an imaging element including a transfer control electrode (charge transfer electrode). FIG. 13 illustrates a schematic partial cross-sectional view of the imaging element of Example 4. FIG. 14A illustrates an equivalent circuit diagram of the imaging element of Example 4. FIG. 15 illustrates a schematic layout diagram of the first electrode, the transfer control electrode, and the charge accumulation electrode, and the transistors included in the controller that are included in the imaging element of Example 4. FIGS. 16 and 17 each schematically illustrates a state of a potential in each part during an operation of the imaging element of Example 4. FIG. 14B illustrates an equivalent circuit diagram for describing each part of the imaging element of Example 4.

The imaging element of Example 4 further includes, between the first electrode 21 and the charge accumulation electrode 24, the transfer control electrode (charge transfer electrode) 25 that is disposed at a distance from the first electrode 21 and the charge accumulation electrode 24 and disposed to be opposed to the photoelectric conversion layer 23A with the insulating layer 82 interposed therebetween. The transfer control electrode 25 is coupled to a pixel drive circuit included in a drive circuit through a coupling hole 68B, a pad section 68A, and a wiring line VOT provided in the interlayer insulating layer 81.

Hereinafter, description is given of an operation of the imaging element of Example 4 with reference to FIGS. 16 and 17. It is to be noted that values of a potential to be applied to the charge accumulation electrode 24 and a potential at a point PC specifically differ between FIGS. 16 and 17.

During a charge accumulation period, from the drive circuit, the potential V11 is applied to the first electrode 21, the potential V31 is applied to the charge accumulation electrode 24, and a potential V41 is applied to the transfer control electrode 25. Light having entered the photoelectric conversion layer 23A is photoelectrically converted in the photoelectric conversion layer 23A. Holes generated by photoelectric conversion are sent from the second electrode 22 to the drive circuit via a wiring line VOU. Meanwhile, because the potential of the first electrode 21 is higher than the potential of the second electrode 22, that is, because a positive potential is to be applied to the first electrode 21 and a negative potential is to be applied to the second electrode 22, V31>V11 (e.g., V31>V11>V41 or V11>V31>V41) holds true. This causes electrons generated by the photoelectric conversion to be attracted to the charge accumulation electrode 24, and to remain in a region of the photoelectric conversion layer 23A, opposed to the charge accumulation electrode 24. That is, electric charge is accumulated in the photoelectric conversion layer 23A. Because V31>V41 holds true, it is possible to reliably prevent the electrons generated inside of the photoelectric conversion layer 23A from moving toward the first electrode 21. With the passage of time of photoelectric conversion, the potential in the region of the photoelectric conversion layer 23A, opposed to the charge accumulation electrode 24 has a more negative value.

A reset operation is performed later in the charge accumulation period. This resets the potential of the floating diffusion layer FD, and the potential of the floating diffusion layer FD shifts to the potential VDD of the power supply.

After completion of the reset operation, the electric charge is read out. That is, during a charge transfer period, from the drive circuit, the potential V12 is applied to the first electrode 21, the potential V32 is applied to the charge accumulation electrode 24, and the potential V42 is applied to the transfer control electrode 25. Here, V32 V42≤V12 (preferably V32<V42<V12) holds true. This causes the electrons remaining in the region of the photoelectric conversion layer 23A opposed to the charge accumulation electrode 24 to be reliably read out to the first electrode 21, and further to the floating diffusion layer FD. That is, the electric charge accumulated in the photoelectric conversion layer 23A is read out to the controller.

This completes the series of operations including the charge accumulation, the reset operation, and the charge transfer.

The operations of the amplification transistor TRamp and the selection transistor TRsel after the electrons are read out to the floating diffusion layer FD are the same as the operations of existing ones of these transistors.

A plurality of transfer control electrodes may be provided from a position closest to the first electrode 21 toward the charge accumulation electrode 24. In addition, Modification Example-2 of Example 3 is applicable. That is, the photoelectric converter may include the upper photoelectric conversion layer (photoelectric conversion layer 23A) and the lower semiconductor layer (oxide semiconductor layer) 23B from the side of the second electrode.

### Example 5

Example 5 is also an application of the quantum dot ensemble layer 10 described in Example 1 and Example 2. In Example 5, the quantum dot ensemble layer 10 is shaped (formed) into a layer on a base 11D. For formation of the quantum dot ensemble layer 10, it is sufficient if the quantum dot dispersion liquid is formed on the base 11D. Here, in the base 11D, various constituent elements included in a light-emitting element are formed. Specifically, the base 11D includes a light-emitting element, more specifically, a surface emitting laser (VCSEL).

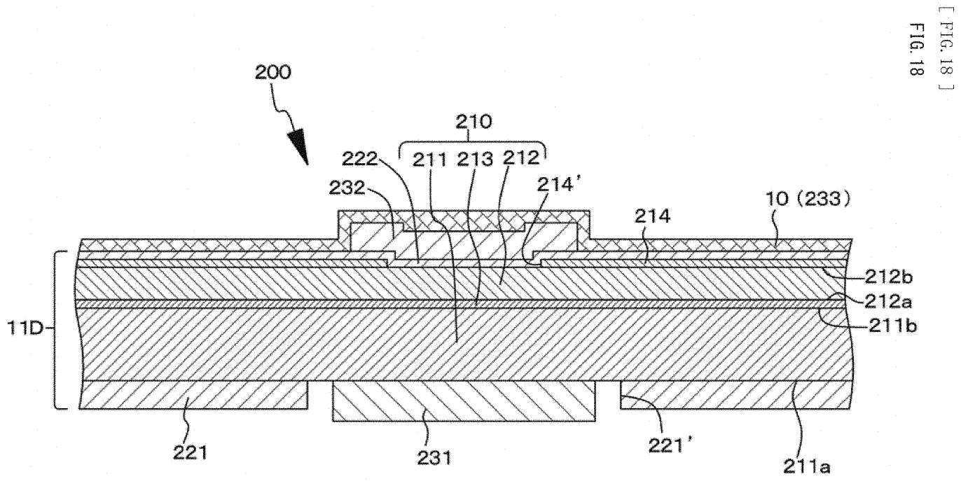

As illustrated in a schematic partial cross-sectional view in FIG. 18, a light-emitting element 200 of Example 5 includes a stacked structure 210 in which a first compound semiconductor layer 211 having a first surface 211a and a second surface 211b opposed to the first surface 211a, an active layer (light-emitting layer) 213 facing the second surface 211b of the first compound semiconductor layer 211, and a second compound semiconductor layer 212 having a first surface 212a facing the active layer 213 and a second surface 212b opposed to the first surface 212a are stacked, a first light reflection layer 231, and a second light reflection layer 232 that is formed on second surface side of the second compound semiconductor layer 212 and has a flat shape.

The stacked structure 210 may include a structure including at least one kind of material selected from a group including GaN-based compound semiconductors, InP-based compound semiconductors, and GaAs-based compound semiconductors. In Example 5, specifically, the stacked structure 210 includes a GaN-based compound semiconductor.

Specifically, the first compound semiconductor layer 211 includes, for example, a n-GaN layer doped with about 2×10¹⁶ cm⁻³ of Si. The active layer 213 includes a five-tiered quantum well structure in which In_{0.04}Ga_{0.96}N layers (barrier layers) and In_{0.16}Ga_{0.84}N layers (well layers) are stacked. The second compound semiconductor layer 212 includes, for example, a p-GaN layer doped with about 1×10¹⁹ cm⁻³ of magnesium. The plane orientation of the first compound semiconductor layer 211 is not limited to a {0001} plane, and may be, for example, a {50-21} plane or the like that is a semipolar plane. The first electrode 221 including Ti/Pt/Au is electrically coupled to an external circuit or the like via a first pad electrode (not illustrated) including, for example, Ti/Pt/Au or V/Pt/Au. Meanwhile, a second electrode 222 is formed on the second compound semiconductor layer 212, and the second light reflection layer 232 is formed on the second electrode 222. The first light reflection layer 231 has a flat shape, and the second light reflection layer 232 on the second electrode 222 also has a flat shape. The second electrode 222 includes a transparent electrically-conductive material, specifically, ITO having a thickness of 30 nm. On an edge part of the second electrode 222, a second pad electrode including, for example, Pd/Ti/Pt/Au, Ti/Pd/Au, or Ti/Ni/Au for establishing electrical coupling to the external circuit or the like may be formed or coupled. The first light reflection layer 231 and the second light reflection layer 232 include a stacked structure of a Ta₂O₅ layer and a SiO₂ layer, or a stacked structure of a SiN layer and a SiO₂ layer. Although the first light reflection layer 231 and the second light reflection layer 232 have such a multilayer structure, they are illustrated as a single layer for simplification of the drawings. Respective planar shapes of the first electrode 221 (specifically, an opening 221′ provided in the first electrode 221), the first light reflection layer 231, the second light reflection layer 232, and an opening 214′ provided in an insulating layer (current confinement layer) 214 are circular.

In order to obtain a current confinement region, the insulating layer (current confinement layer) 214 including an insulating material (e.g., SiOX or SiNX, AlOX) may be formed between the second electrode 222 and the second compound semiconductor layer 212, and the insulating layer (current confinement layer) 214 has the opening 214′ for injecting a current into the second compound semiconductor layer 212. Alternatively, in order to obtain the current confinement region, the second compound semiconductor layer 212 may be etched by an RIE method or the like to form a mesa structure. Alternatively, the current confinement region may be formed by partially oxidizing some layers of stacked second compound semiconductor layers 22 from a lateral direction, Alternatively, the current confinement region including a region with a reduced electrical conductivity may be formed by injecting an impurity (e.g., boron) into the second compound semiconductor layer 212 by ion injection. Alternatively, any of them may be combined appropriately. Note that it is necessary for the second electrode 222 to be electrically coupled to a portion (current injection region) of the second compound semiconductor layer 212 through which a current flows due to current confinement.

In an example illustrated in FIG. 18, the second electrode 222 is coupled to the external circuit or the like via the first pad electrode (not illustrated). The first electrode 221 is also coupled to the external circuit or the like via the first pad electrode (not illustrated). Light is outputted to outside via the second light reflection layer 232.

In addition, in the light-emitting element 200 of Example 5, a wavelength conversion material layer (color conversion material layer) 233 is provided in a light emitting region of the light-emitting element 200. The wavelength conversion material layer (color conversion material layer) 233 includes the quantum dot ensemble layer 10. More specifically, the wavelength conversion material layer 233 (quantum dot ensemble layer 10) is formed on the second electrode 222 and the second light reflection layer 232. In addition, for example, white light is outputted through the wavelength conversion material layer (color conversion material layer) 233. In a case where light produced by the active layer 213 is to be outputted to outside through the second light reflection layer 232, it is sufficient if the wavelength conversion material layer (color conversion material layer) 233 is formed on light output side of the second light reflection layer 232. It is to be noted that the light produced by the active layer 213 is to be outputted to outside through the first light reflection layer 231, it is sufficient if the wavelength conversion material layer (color conversion material layer) 233 is formed on light output side of the first light reflection layer 231.

The configuration and structure of the light-emitting element of Example 5 may be similar to the configuration and structure of a known light-emitting element.

Although the quantum dot ensemble and the manufacturing method thereof, and the quantum dot ensemble layer of the present disclosure have been described above on the basis of preferred Examples, the quantum dot ensemble and the manufacturing method thereof, and the quantum dot ensemble layer of the present disclosure are not limited to these Examples. Materials and manufacturing conditions used for manufacturing of the quantum dot ensemble and the quantum dot ensemble layer are illustrative, and the configurations and structures of the quantum dot ensemble, the quantum dot ensemble layer, and the base are also illustrative, and may be modified as appropriate. A quantum dot ensemble that includes a combination of one kind of material, as the material included in the core, selected from a group including various materials described above from Si to TiO2 and one kind of material, as the shell, selected from a group including various materials (ZnS, ZnSe, ZnTe, CdS, and CdSe) described above, or the quantum dot ensemble and the quantum dot ensemble layer may be substantially manufactured on the basis of a manufacturing method similar to those described in Example 1 and Example 2, and various physical properties of the obtained quantum dot ensemble also have values similar to values of various physical properties of the quantum dot ensemble obtained in Example 1.

The configurations, structures, manufacturing conditions, manufacturing methods, used materials of the imaging element and imaging device described in Example 3 and Example 4 are illustrative, and may be modified as appropriate. In Example 3 and Example 4, an electron serves as signal charge, and the electrical conductivity type of the photoelectric conversion layer formed on the semiconductor substrate is of n-type; however, application to an imaging device in which a hole serves as signal charge is also possible. In this case, it is sufficient if each semiconductor region includes a semiconductor region of an opposite electrical conductivity type, and the electrical conductivity type of the photoelectric conversion layer formed on the semiconductor substrate is of p-type.

In addition, in Examples, description has been given with reference to, as an example, a case of application to a CMOS type imaging device in which unit pixels are arranged in a matrix for sensing signal charge corresponding to the amount of incident light as a physical quantity; however, the application to the CMOS type imaging device is not limitative, and application to a CCD type imaging device is also possible. In the latter case, the signal charge is transferred in the vertical direction by a vertical transfer register of a CCD type structure, transferred in a horizontal direction by a horizontal transfer register, and then amplified to thereby cause a pixel signal (image signal) to be outputted. In addition, possible applications are not limited to column-system imaging devices in general in which pixels are formed in a two-dimensional matrix pattern and a column signal processing circuit is disposed for each pixel column. Furthermore, in some cases, the selection transistor may be omitted.

Further, the imaging element of the present disclosure is applicable not only to an imaging device that senses the distribution of incident amount of visible light to capture an image of the distribution, but also to an imaging device that captures an image of the distribution of incident amount of infrared rays, X-rays, particles, or the like. In addition, in a broad sense, the imaging element of the present disclosure is generally applicable to an imaging device (physical quantity distribution sensing device) that senses the distribution of other physical quantities, including pressure and capacitance, to capture an image of the distribution, such as a fingerprint detection sensor.

Further, possible applications are not limited to an imaging device that sequentially scans unit pixels in an imaging region row by row and reads out pixel signals from the unit pixels. Application to an X-Y address type imaging device is also possible that selects any pixel on a per-pixel basis and reads out a pixel signal from the selected pixel on a per-pixel basis. The imaging device may be formed in a one-chip form or may be in a modular form with an imaging function in which an imaging region and a drive circuit or an optical system are packaged together.

The technology according to the present disclosure (the present technology) is applicable to various products. For example, the technology according to the present disclosure may be implemented as a device to be mounted on any type of mobile body such as an automobile, an electric vehicle, a hybrid electric vehicle, a motorcycle, a bicycle, a personal mobility, an airplane, a drone, a vessel, or a robot.

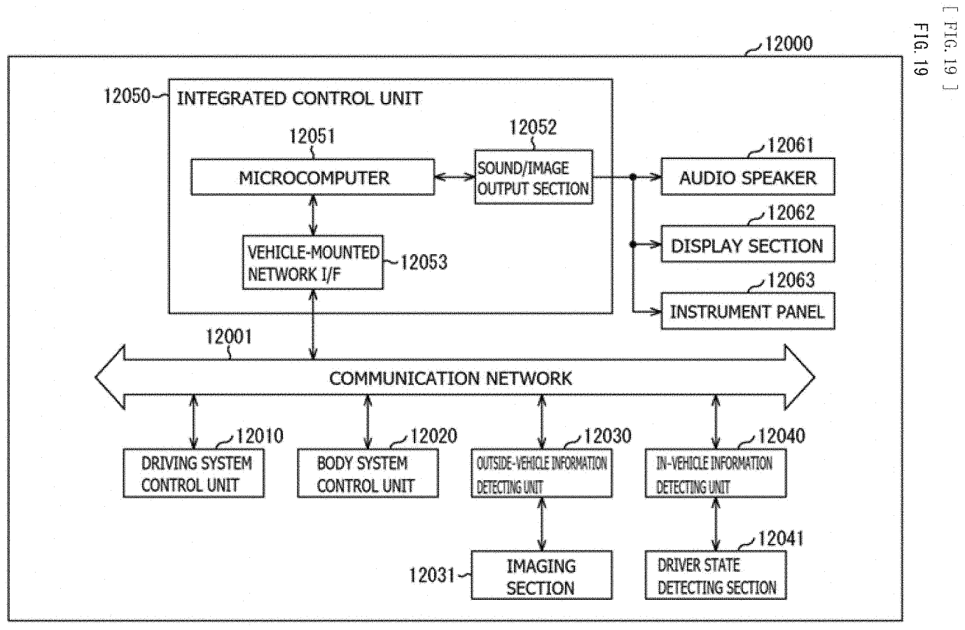

FIG. 19 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 19, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 19, an audio speaker 12061, a display section 12062, and an instrument panel 12063 are illustrated as the output device. The display section 12062 may, for example, include at least one of an on-board display and a head-up display.

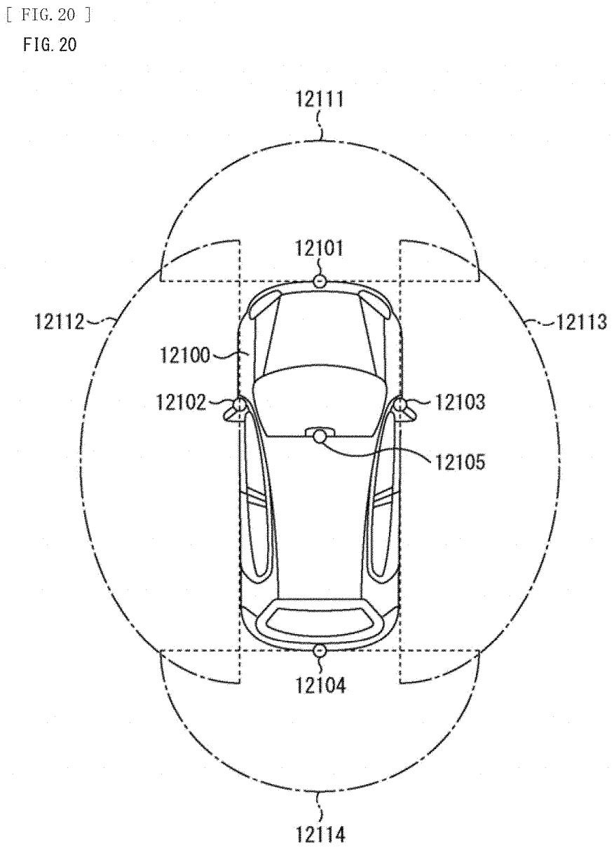

FIG. 20 is a diagram depicting an example of the installation position of the imaging section 12031.

In FIG. 20, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 20 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In addition, for example, the technology according to the present disclosure may be applied to an endoscopic surgery system.

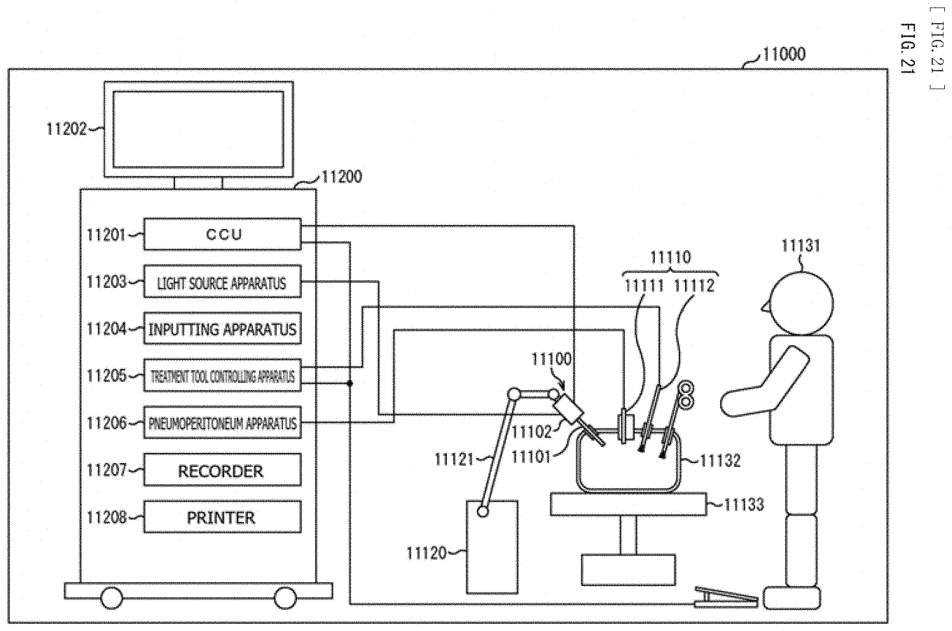

FIG. 21 is a view depicting an example of a schematic configuration of an endoscopic surgery system to which the technology according to an embodiment of the present disclosure (present technology) can be applied.

In FIG. 21, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

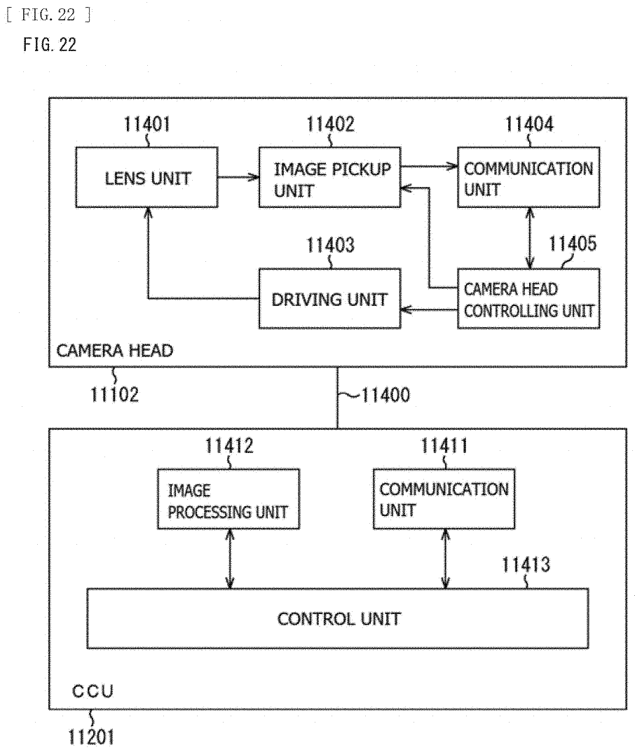

FIG. 22 is a block diagram depicting an example of a functional configuration of the camera head 11102 and the CCU 11201 depicted in FIG. 21.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

It is to be noted that while the description has been given here of the endoscopic surgery system as one example, the technology according to the present disclosure may also be applied to, for example, a micrographic surgery system and the like.

It is to be noted that the present disclosure may also have the following configurations.

### [A01]<Method of Manufacturing Quantum Dot Ensemble: First Aspect>

the quantum dot ensemble including

a plurality of core-shell quantum dots that each includes a core including a compound semiconductor, and a shell including a compound semiconductor and covering the core, and

a ligand coordinated to the shell,

the manufacturing method including mixing a core material, a shell material, and the ligand in a solvent and thereafter performing heating to thereby form the core-shell quantum dots each including the shell covering the core, coordinate the ligand to the shell, and cleave the ligand.

### [A02]<Method of Manufacturing Quantum Dot Ensemble: Second Aspect>

A manufacturing method of a quantum dot ensemble,

the quantum dot ensemble including

a plurality of core-shell quantum dots that each includes a core including a compound semiconductor, and a shell including a compound semiconductor and covering the core, and

a ligand coordinated to the shell,

the manufacturing method including preparing the core-shell quantum dots and mixing the quantum dots and the ligand in a solvent and thereafter performing heating to thereby coordinate the ligand to the shell and cleave the ligand.

### [A03]

The manufacturing method of the quantum dot ensemble according to [A01] or [A02], in which heating conditions include 230° C. or higher for 0.5 hours or more.

### [A04]

The manufacturing method of the quantum dot ensemble according to any one of [A01] to [A03], in which the chalcogen atom is a part of chalcogen atoms included in a front surface of the shell.

### [A05]

The manufacturing method of the quantum dot ensemble according to any one of [A01 to [A04], in which the ligand before being cleaved includes an alkane having a carbon number of 6 or more and including a chalcogen atom at one end.

### [A06]

The manufacturing method of the quantum dot ensemble according to [A05], in which the cleaved ligand includes an alkane including a chalcogen atom at one end and having an average carbon number of 1 or more and 3 or less.

### [A07]

The manufacturing method of the quantum dot ensemble according to [A05] or [A06], in which the ligand before being cleaved includes dodecanethiol or dodecaneselenol.

### [A08]

The manufacturing method of the quantum dot ensemble according to any one of [A01] to [A07], in which the shell includes a sulfide, a selenide, or a telluride.

### [A09]

The manufacturing method of the quantum dot ensemble according to [A08], in which the chalcogen atom at the one end of the ligand and a chalcogen atom included in the shall are the same atoms.

### [A10]

The manufacturing method of the quantum dot ensemble according to [A09], in which the shell includes ZnS.

### [A11]

The manufacturing method of the quantum dot ensemble according to [A10], in which the chalcogen atom at the one end of the ligand includes a sulfur (S) atom.

### [A12]

The manufacturing method of the quantum dot ensemble according to [A11], in which the one end of the ligand includes thiol.

### [A13]

The manufacturing method of the quantum dot ensemble according to [A09], in which the shell includes ZnSe.

### [A14]

The manufacturing method of the quantum dot ensemble according to [A13], in which the chalcogen atom at the one end of the ligand includes a selenium (Se) atom.

### [A15]

The manufacturing method of the quantum dot ensemble according to [A14], in which the one end of the ligand includes selenol.

### [A16]

The manufacturing method of the quantum dot ensemble according to [A09], in which the shell includes ZnTe.

### [A17]

The manufacturing method of the quantum dot ensemble according to [A16], in which the chalcogen atom at the one end of the ligand includes a tellurium (Te) atom.

### [A18]

The manufacturing method of the quantum dot ensemble according to [A17], in which the one end of the ligand includes tellurol.

### [A19]

The manufacturing method of the quantum dot ensemble according to [A09], in which the shell includes CdS.

### [A20]

The manufacturing method of the quantum dot ensemble according to [A19], in which the chalcogen atom at the one end of the ligand includes a sulfur (S) atom.

### [A21]

The manufacturing method of the quantum dot ensemble according to [A20], in which the one end of the ligand includes thiol.

### [A22]

The manufacturing method of the quantum dot ensemble according to [A09], in which the shell includes CdSe.

### [A23]

The manufacturing method of the quantum dot ensemble according to [A22], in which the chalcogen atom at the one end of the ligand includes a selenium (Se) atom.

### [A24]

The manufacturing method of the quantum dot ensemble according to [A23], in which the one end of the ligand includes selenol.

### [A25]

The manufacturing method of the quantum dot ensemble according to any one of [A01] to [A24], in which the core includes a compound semiconductor of Group 4 to Group 6, a compound semiconductor of Group 3 to Group 5, a compound semiconductor of Group 2 to Group 6, or a compound semiconductor including a combination of three or more elements of Group 2, Group 3, Group 4, Group 5, and Group 6.

### [A26]

The manufacturing method of the quantum dot ensemble according to any one of [A01] to [A25], in which an average distance between a quantum dot and a quantum dot is greater than 0 nm and 1 nm or less.

### [A27]

The manufacturing method of the quantum dot ensemble according to any one of [A01] to [A26], in which, when, in ligands of which cleavage does not progress, a peak of hydrogen bonded to carbon adjacent to a chalcogen atom in a ligand absorbed to the shell is taken as 1.00, in cleaved ligands, a peak of hydrogen bonded to carbon adjacent to a chalcogen atom in a ligand absorbed to the shell is 0.3 or less.

### [B01]<Quantum Dot Ensemble>

A quantum dot ensemble including:

a plurality of core-shell quantum dots that each includes a core including a compound semiconductor, and a shell including a compound semiconductor and covering the core; and

a ligand coordinated to the shell,

the ligand including an alkane that has an average carbon number of 1 or more and 3 or less and includes a chalcogen atom at one end.

### [B02]

The quantum dot ensemble according to [B001], in which the chalcogen atom is a part of chalcogen atoms included in a front surface of the shell.

### [B03]

The quantum dot ensemble according to [B01] or [B02], in which the shell includes a sulfide, a selenide, or a telluride.

### [B04]

The quantum dot ensemble according to any one of [B01] to [B03], in which the chalcogen atom at the one end of the ligand and a chalcogen atom included in the shall are the same atoms.

### [B05]

The quantum dot ensemble according to [B04], in which the shell includes ZnS.

### [B06]

The quantum dot ensemble according to [B05], in which the chalcogen atom at the one end of the ligand includes a sulfur (S) atom.

### [B07]

The quantum dot ensemble according to [B06], in which the one end of the ligand includes thiol.

### [B08]

The quantum dot ensemble according to [B04], in which the shell includes ZnSe.

### [B09]

The quantum dot ensemble according to [B08], in which the chalcogen atom at the one end of the ligand includes a selenium (Se) atom.

### [B10]

The quantum dot ensemble according to [B09], in which the one end of the ligand includes selenol.

### [B11]

The quantum dot ensemble according to [B04], in which the shell includes ZnTe.

### [B12]

The quantum dot ensemble according to [B11], in which the chalcogen atom at the one end of the ligand includes a tellurium (Te) atom.

### [B13]

The quantum dot ensemble according to [B12], in which the one end of the ligand includes tellurol.

### [B14]

The quantum dot ensemble according to [B04], in which the shell includes CdS.

### [B15]

The quantum dot ensemble according to [B14], in which the chalcogen atom at the one end of the ligand includes a sulfur (S) atom.

### [B16]

The quantum dot ensemble according to [B15], in which the one end of the ligand includes thiol.

### [B17]

The quantum dot ensemble according to [B04], in which the shell includes CdSe.

### [B18]

The quantum dot ensemble according to [B17], in which the chalcogen atom at the one end of the ligand includes a selenium (Se) atom.

### [B19]

The quantum dot ensemble according to [B18], in which the one end of the ligand includes selenol.

### [B20]

The quantum dot ensemble according to any one of [B01] to [B19], in which the core includes a compound semiconductor of Group 4 to Group 6, a compound semiconductor of Group 3 to Group 5, a compound semiconductor of Group 2 to Group 6, or a compound semiconductor including a combination of three or more elements of Group 2, Group 3, Group 4, Group 5, and Group 6.

### [B21]

The quantum dot ensemble according to any of [B01] to [B20], in which an average distance between a quantum dot and a quantum dot is greater than 0 nm and 1 nm or less.

### [B22]

The quantum dot ensemble according to any one of [B01] to [B21], further including a dispersion medium, the quantum dot ensemble being dispersed in the dispersion medium.

### [B23]

The quantum dot ensemble according to any of [B01] to [B22], in which when, in ligands of which cleavage does not progress, a peak of hydrogen bonded to carbon adjacent to a chalcogen atom in a ligand absorbed to the shell is taken as 1.00, in cleaved ligands, a peak of hydrogen bonded to carbon adjacent to a chalcogen atom in a ligand absorbed to the shell is 0.3 or less.

### [C01]<Quantum Dot Ensemble Layer>

A quantum dot ensemble layer including a quantum dot ensemble shaped into a layer, the quantum dot ensemble including

a plurality of core-shell quantum dots that each includes a core including a compound semiconductor, and a shell including a compound semiconductor and covering the core, and

a ligand coordinated to the shell, and

the ligand including an alkane that has an average carbon number of 1 or more and 3 or less and includes a chalcogen atom at one end.

### [C02]

The quantum dot ensemble layer according to [C001], in which the chalcogen atom is a part of chalcogen atoms included in a front surface of the shell.

### [C03]

The quantum dot ensemble layer according to [C01] or [C02], in which the shell includes a sulfide, a selenide, or a telluride.

### [C04]

The quantum dot ensemble layer according to any one of [C01] to [C03], in which the chalcogen atom at the one end of the ligand and a chalcogen atom included in the shall are the same atoms.

### [C05]

The quantum dot ensemble layer according to [C04], in which the shell includes ZnS.

### [C06]

The quantum dot ensemble layer according to [C05], in which the chalcogen atom at the one end of the ligand includes a sulfur (S) atom.

### [C07]

The quantum dot ensemble layer according to [C06], in which the one end of the ligand includes thiol.

### [C08]

The quantum dot ensemble layer according to [C04], in which the shell includes ZnSe.

### [C09]

The quantum dot ensemble layer according to [C08], in which the chalcogen atom at the one end of the ligand includes a selenium (Se) atom.

### [C10]

The quantum dot ensemble layer according to [C09], in which the one end of the ligand includes selenol.

### [C10]

The quantum dot ensemble layer according to [C04], in which the shell includes ZnTe.

### [C12]

The quantum dot ensemble layer according to [C11], in which the chalcogen atom at the one end of the ligand includes a tellurium (Te) atom.

### [C13]

The quantum dot ensemble layer according to [C12], in which the one end of the ligand includes tellurol.

### [C14]

The quantum dot ensemble layer according to [C04], in which the shell includes CdS.

### [C15]

The quantum dot ensemble layer according to [C14], in which the chalcogen atom at the one end of the ligand includes a sulfur (S) atom.

### [C16]

The quantum dot ensemble layer according to [C15], in which the one end of the ligand includes thiol.

### [C17]

The quantum dot ensemble layer according to [C04], in which the shell includes CdSe.

### [C18]

The quantum dot ensemble layer according to [C17], in which the chalcogen atom at the one end of the ligand includes a selenium (Se) atom.

### [C19]

The quantum dot ensemble layer according to [C18], in which the one end of the ligand includes selenol.

### [C20]

The quantum dot ensemble layer according to any one of [C01] to [C19], in which the core includes a compound semiconductor of Group 4 to Group 6, a compound semiconductor of Group 3 to Group 5, a compound semiconductor of Group 2 to Group 6, or a compound semiconductor including a combination of three or more elements of Group 2, Group 3, Group 4, Group 5, and Group 6.

### [C21]

The quantum dot ensemble layer according to any one of [C01] to [C20], in which an average distance between a quantum dot and a quantum dot is greater than 0 nm and 1 nm or less.

### [C22]

The quantum dot ensemble layer according to any one of [C01] to [C21], in which the quantum dot ensemble is shaped into a layer on a base.

### [C23]

The quantum dot ensemble layer according to any one of [C01] to [C21], in which the quantum dot ensemble is shaped into a layer on a functional layer provided on a base.

### [C24]

The quantum dot ensemble layer according to any one of [C01] to [C23], in which when, in ligands of which cleavage does not progress, a peak of hydrogen bonded to carbon adjacent to a chalcogen atom in a ligand absorbed to the shell is taken as 1.00, in cleaved ligands, a peak of hydrogen bonded to carbon adjacent to a chalcogen atom in a ligand absorbed to the shell is 0.3 or less.

### [D01]<<Imaging Device>>

An imaging device including a plurality of imaging elements arranged, the imaging elements each having a stacked structure in which a first electrode, a photoelectric conversion layer including a quantum dot ensemble layer, and a second electrode are stacked,

the quantum dot ensemble layer including a quantum dot ensemble shaped in a layer,

the quantum dot ensemble including

a plurality of core-shell quantum dots that each includes a core including a compound semiconductor, and a shell including a compound semiconductor and covering the core, and

a ligand coordinated to the shell, and

the ligand including an alkane that has an average carbon number of 1 or more and 3 or less and includes a chalcogen atom at one end.

### [D02]<<Imaging Device>>

An imaging device including a plurality of imaging elements arranged, the imaging elements each having a stacked structure in which a first electrode, a photoelectric conversion layer including a quantum dot ensemble layer, and a second electrode are stacked,

the quantum dot ensemble layer including the quantum dot ensemble layer according to any one of [C01] to [C24].

### [E01]

The imaging device according to [D01] or [D02], in which the imaging elements each further include a charge accumulation electrode that is disposed at a distance from the first electrode and is disposed to be opposed to the photoelectric conversion layer.

### [E02]

The imaging device according to [E01], in which a photoelectric converter includes the photoelectric conversion layer and an oxide semiconductor layer from side of the second electrode.

### [F01]<<Imaging Element>>

An imaging element including a stacked structure in which a first electrode, a photoelectric conversion layer including a quantum dot ensemble layer, and a second electrode are stacked,

the quantum dot ensemble layer including the quantum dot ensemble layer according to any one of [C01] to [C24].

### [F02]<<Imaging Device>>

An imaging device including a plurality of the imaging elements according to [F01].

This application claims the benefit of Japanese Priority Patent Application JP2020-096604 filed with Japan Patent Office on Jun. 3, 2020, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A manufacturing method of a quantum dot ensemble,
the quantum dot ensemble including
a plurality of core-shell quantum dots that each includes a core including a compound semiconductor, and a shell including a compound semiconductor and covering the core, and
a ligand coordinated to the shell,
the manufacturing method comprising mixing a core material, a shell material, and the ligand in a solvent and thereafter performing heating to thereby form the core-shell quantum dots each including the shell covering the core, coordinate the ligand to the shell, and cleave the ligand.

2. The manufacturing method of the quantum dot ensemble according to claim 1, wherein heating conditions include 230° C. or higher for 0.5 hours or more.

3. The manufacturing method of the quantum dot ensemble according to claim 1, wherein the ligand before being cleaved includes an alkane having a carbon number of 6 or more and including a chalcogen atom at one end.

4. The manufacturing method of the quantum dot ensemble according to claim 3, wherein the cleaved ligand includes an alkane including a chalcogen atom at one end and having an average carbon number of 1 or more and 3 or less.

5. The manufacturing method of the quantum dot ensemble according to claim 3, wherein the ligand before being cleaved includes dodecanethiol or dodecaneselenol.

6. The manufacturing method of the quantum dot ensemble according to claim 1, wherein the shell includes a sulfide, a selenide, or a telluride.

7. The manufacturing method of the quantum dot ensemble according to claim 1, wherein the core includes a compound semiconductor of Group 4 to Group 6, a compound semiconductor of Group 3 to Group 5, a compound semiconductor of Group 2 to Group 6, or a compound semiconductor including a combination of three or more elements of Group 2, Group 3, Group 4, Group 5, and Group 6.

8. The manufacturing method of the quantum dot ensemble according to claim 1, wherein an average distance between a quantum dot and a quantum dot is greater than 0 nm and 1 nm or less.

9. A manufacturing method of a quantum dot ensemble,
the quantum dot ensemble including
a plurality of core-shell quantum dots that each includes a core including a compound semiconductor, and a shell including a compound semiconductor and covering the core, and
a ligand coordinated to the shell,
the manufacturing method comprising preparing the core-shell quantum dots and mixing the quantum dots and the ligand in a solvent and thereafter performing heating to thereby coordinate the ligand to the shell and cleave the ligand.

10. A quantum dot ensemble comprising:
a plurality of core-shell quantum dots that each includes a core including a compound semiconductor, and a shell including a compound semiconductor and covering the core; and
a ligand coordinated to the shell,
the ligand including an alkane that has an average carbon number of 1 or more and 3 or less and includes a chalcogen atom at one end.

11. The quantum dot ensemble according to claim 10, wherein the shell includes a sulfide, a selenide, or a telluride.

12. The quantum dot ensemble according to claim 10, wherein the core includes a compound semiconductor of Group 4 to Group 6, a compound semiconductor of Group 3 to Group 5, a compound semiconductor of Group 2 to Group 6, or a compound semiconductor including a combination of three or more elements of Group 2, Group 3, Group 4, Group 5, and Group 6.

13. The quantum dot ensemble according to claim 10, wherein an average distance between a quantum dot and a quantum dot is greater than 0 nm and 1 nm or less.

14. The quantum dot ensemble according to claim 10, further comprising a dispersion medium, the quantum dot ensemble being dispersed in the dispersion medium.

15. A quantum dot ensemble layer comprising a quantum dot ensemble shaped into a layer, the quantum dot ensemble including
a plurality of core-shell quantum dots that each includes a core including a compound semiconductor, and a shell including a compound semiconductor and covering the core, and
a ligand coordinated to the shell, and
the ligand including an alkane that has an average carbon number of 1 or more and 3 or less and includes a chalcogen atom at one end.

16. An imaging device comprising a plurality of imaging elements arranged, the imaging elements each having a stacked structure in which a first electrode, a photoelectric conversion layer including a quantum dot ensemble layer, and a second electrode are stacked,
the quantum dot ensemble layer including a quantum dot ensemble shaped in a layer,
the quantum dot ensemble including
a plurality of core-shell quantum dots that each includes a core including a compound semiconductor, and a shell including a compound semiconductor and covering the core, and
a ligand coordinated to the shell, and
the ligand including an alkane that has an average carbon number of 1 or more and 3 or less and includes a chalcogen atom at one end.
